(19) United States
(12) Patent Application Publication
(10) Pub. No.: US 2020/0131025 A1
(43) Pub. Date: Apr. 30, 2020

(54) WAVE PROPAGATION COMPUTING DEVICES FOR MACHINE LEARNING

(71) Applicant: CYMATICS LABORATORIES CORP., Pittsburgh, PA (US)

(72) Inventors: Rajarishi Sinha, Pittsburgh, PA (US); David Francois Guillou, Pittsburgh, PA (US)

(73) Assignee: CYMATICS LABORATORIES CORP., Pittsburgh, PA (US)

(21) Appl. No.: 16/622,165

(22) PCT Filed: Jun. 12, 2018
(86) PCT No.: PCT/US2018/037009

§ 371 Date: Dec. 12, 2019

Related U.S. Application Data
(60) Provisional application No. 62/520,167, filed on Jun. 15, 2017.

(51) Int. Cl. B81B 3/00; H01L 41/09; H01L 27/20; G06N 3/04

(52) U.S. Cl. CPC B81B 3/0021; G06N 3/04; H01L 27/20; H01L 41/0986

(57) ABSTRACT

Embodiments of the present technology may be directed to wave propagation computing (WPC) device(s), such as an acoustic wave reservoir computing (AWRC) device, that performs computations by random projection. In some embodiments, the AWRC device is used as part of a machine learning system or as part of a more generic signal analysis system. The AWRC device takes in multiple electrical input signals and delivers multiple output signals. It performs computations on these input signals to generate the output signals. It performs the computations using acoustic (or electro-mechanical) components and techniques, rather than using electronic components (such as CMOS logic gates or MOSFET transistors) as is commonly done in digital reservoirs.

### CROSS-REFERENCE TO RELATED APPLICATION

The present application claims the benefit of the filing date of U.S. Provisional Application No. 62/520,167 filed Jun. 15, 2017, the disclosure of which is hereby incorporated herein by reference.

### TECHNICAL FIELD

The present technology concerns a wave propagation computing (WPC) device, such as an acoustic wave reservoir computing (AWRC) device, for performing computations by random projection. In some applications, the AWRC device may be used for signal analysis or machine learning.

### BACKGROUND

The field of computer and information technology is being impacted simultaneously by two fundamental changes: (1) the types and quantity of data being collected is growing exponentially; and (2) the increase in raw computing power over time (i.e. Moore's Law) is slowing down and may stop altogether within 10 years.

It is estimated that human activity generates 2.5 quintillion (2.5×10¹⁸) bytes of data per day. Up to the recent past, recorded data consisted mostly of text and sound, both of which are dense data and form comparatively small data sets. Today, much of the recorded data consists of images and videos, which both possesses attributes (or features) that number from the thousands to the millions, and both are typically extremely sparse. This new state of fact is often called Big Data.

Data is converted into useful information using computer hardware and algorithms. Traditional statistical analysis techniques were developed for smaller and denser data sets, and require prohibitive resources (in cost of computer hardware, and cost of electrical power) to process large and sparse data sets. To convert image and video data into useful information, we need new analysis algorithms (and the appropriate computer hardware) that do not consume prohibitive amounts of power.

Moore's Law has been the driving force behind the computer revolution (cf. FIG. 1 from Gordon Moore, “Cramming more Components onto Integrated Circuits”, Electronics, 38(8), Apr. 19, 1965), which is incorporated by reference herein. Applicant incorporates by reference all references cited herein. However, as many articles in the recent literature have observed (cf. “Rebooting Computing”, IEEE Computer, December 2015), the semiconductor manufacturing processes needed to continue shrinking the size (and increase the speed) of transistors will reach atomic scale resolution by the mid-2020s. As a result, the cost and speed of new computer chips is expected to level off within 10 years, and the computer revolution risks slowing down or stopping altogether.

### I. Neural Networks

One approach being pursued to process large and sparse data sets effectively despite the slowdown of computer chip development is the use of artificial (i.e. electronic) neural networks (NN) (cf. Jüurgen Schmidhuber, “Deep learning in neural networks: An overview”, Neural Networks, Volume 61, January 2015, p. 85-117). Artificial neural networks are formed of electronic processing elements that are interconnected in a network that loosely mimics those found in the brain. Every electronic neuron outputs a weighted (and, optionally, non-linearly convolved) average of its inputs. The network as a whole transforms one or more inputs to one or more outputs. Artificial neural networks are already used to analyze pictures and video in demanding applications such as self-driving vehicles.

### A. Feed-Forward Neural Networks

The feed-forward neural network was the first type of neural network that was invented (cf. Simon Haykin in Nonlinear Dynamical Systems: Feedforward Neural Network Perspectives, Wiley Publishers, ISBN: 978-0-471-34911-2, February 2001). In such a network, there are no cycles in the interconnect network. The information moves in one direction, from in the inputs to the outputs, via the interconnected neurons. The neurons are typically organized in layers, with each layer taking as input the outputs from the previous layer. The inputs to the first layer are the network inputs. The outputs from the last layer are the network outputs. The intermediate layers are called “hidden layers”. FIG. 2 shows an example of feed-forward neural network. Most feed-forward neural networks, from a simple feed-forward network with a single hidden layer to the state-of-the-art convolutional neural networks currently used for image analysis, are variations on the fundamental Multi-Layer Perceptron (MLP) scheme depicted on FIG. 2.

### B. Recurrent Neural Networks

Recurrent Neural Networks (RNN) are a class of neural network architectures. They were proposed to extend traditional neural networks to the modeling of dynamical systems by introducing cycles in the neuronal interconnections (cf. Zachary C. Lipton, John Berkowitz, Charles Elkan, “A Critical Review of Recurrent Neural Networks for Sequence Learning”, arXiv: 1506.00019 [cs.LG]). FIG. 3 shows an example of a RNN. It is a modification of the feed-forward neural network shown on FIG. 2. Cycles have been added from the output layer to the hidden layers, and within the hidden layers. The cycles implement a form of short-term memory by transferring the state of certain neurons at timestep (or iteration) t back into the network at timestep (or iteration) t+1. RNNs and their variants have been successfully used to model or analyze speech, text and other dynamical data streams where there are correlations over time.

### C. Digital Circuit Implementations of Neural Networks

Neural networks have traditionally been implemented on general-purpose CPUs. But, neural network computational techniques are resource-intensive; even a moderately-complex neural network architecture requires significant computational resources—CPU time, memory and storage. For example, GoogLeNet (cf. Szegedy et al, “Going Deeper with Convolutions”, Proceedings of the Computer Vision and Pattern Recognition (CVPR) Conference, 2015) uses 22 layers and requires over 6.8 million parameters and 1.5 billion operations to characterize and run the network. This high resource requirement was one of the reasons that neural networks remained at the fringes of computer science until faster computer technology and cheap memory and storage became widely available.

One approach to reducing the computation time is to use graphical processing units (GPUs). GPUs were originally created to perform specialized mathematical computations necessary for graphical processing, 3D modeling and graphical video games. They were later repurposed to handle the mathematics and the large data sets used in deep (multi-layer) neural networks (cf. A. Krizhevsky, I. Sutskever, and G. Hinton, “ImageNet classification with deep convolutional neural networks”, In Advances in Neural Information Processing Systems 25, pages 1106-1114, 2012). GPUs have become the standard hardware for production neural networks and are widely used in industry. However, GPUs consume 100's of watts of power, and must be placed on cooled racks, and are therefore not suitable for portable applications.

It is worth noting that GPUs are not optimized specifically for neural networks; they contain circuits that provide several other specialized functions for 2D and 3D image and video applications. An ASIC specifically designed and optimized for neural networks would yield benefits at economies of scale, at the cost of a significant up-front investment. The Google Tensor-Processing Unit (TPU) (cf. Google Cloud Platform Blog, https://cloudplatform.googleblog.com/2017/04/quantifying-the-performance-of-the-TPU-our-first-machine-learning-chip.html, retrieved on May 16, 2017) is one such ASIC. The TPU is smaller and less power-hungry than a GPU—about the size of a typical hard drive—but must still be rack-mounted. The architecture of the TPU is reported in U.S. Patent Publication Nos. 2016/0342889A1, 2016/0342890A1, 2016/0342891A1 and 2016/0342892A1.

Movidius, Inc. is a company that makes a vision processor that is programmable to different architectures (cf. David Moloney, “1TOPS/W software programmable media processor”, Hot Chips 23 Symposium (HCS), 2011). Movidius was recently acquired by Intel Corp. Movidius' technology is based on best architectural practices from GPUs, ASICs and FPGAs (Field-Programmable Gate Arrays).

Nervana Systems, Inc., a company that was recently acquired by Intel Corp. (cf. Jeremy Hsu, “Nervana systems: Turning neural networks into a service”, IEEE Spectrum, 53(6):19-19, 19 May 2016), has developed a custom ASIC that is interconnected with other ASICs and dedicated memory to perform neural network computations. The system is available as a cloud-based service.

However, to achieve high performance, digital circuit implementations of neural networks require the use of the most advanced, and therefore the most expensive, semiconductor circuit manufacturing technologies available to-date, which result in a high per-unit cost of digital neural networks.

### D. Analog Circuit Implementations of Neural Networks

The digital approaches summarized above are all based on a Von Neumann architecture—programs and data are held in a common memory store, and an instruction and data operation cannot occur simultaneously. A different approach is to implement the neural network in analog circuits, with analog-to-digital and digital-to-analog conversion circuits to transfer inputs and outputs on and off chip. Analog circuits have the advantage over digital circuits that low-resolution analog computation circuits (such as adders and multipliers) require fewer transistors than corresponding-resolution digital computation circuits, and therefore have a lower cost of manufacturing and lower power consumption.

AT&T developed the ANNA neural network chip in the 1990s (cf. Eduard Sackinger et al., “Application of the ANNA Neural Network Chip to High-Speed Character Recognition”, IEEE Transactions on Neural Networks, 1992, 3(3):498-505). It was manufactured in 0.9 um CMOS technology, with 180,000 transistors that implemented 4096 synapses. It was capable of recognizing 1000 handwritten characters per second.

More recently, IBM Corp. has developed TrueNorth, a 5.4 billion transistor chip that combines 1 million spiking neurons and 256 million synapses (cf. Paul A. Merolla et al., “A million spiking-neuron integrated circuit with a scalable communication network and interface”, Science, 8 Aug. 2014, 345(6197):668-673). TrueNorth can process an input stream of 400-pixel-by-240-pixel video at 30 frames per second, and perform multi-object detection at a power consumption of 63 mW.

However, with every new generation of CMOS technology below 65 nm, analog circuits lose some of their performance advantage over digital circuits: the voltage gain of MOSFETs keeps decreasing, and the performance variability between MOSFETS that are designed to be identical keeps increasing. Both of these basic trends make analog circuits larger and more complex (to make up for the poor voltage gain or/and to correct transistor-to-transistor variability issues), which directly increases the size and power consumption of analog circuits, and thus decreases their performance advantage over digital circuits. As a result, analog circuit implementations of neural networks offer only a limited cost and power improvement over digital circuit neural networks, and alternate fabrication methods or/and computing schemes are needed.

### E. Optics-Based Implementations of Neural Networks

Recently, there has been an interest in using optical technologies to perform certain computations for neural network applications. It is hoped that optics-based computational circuits will achieve a much higher speed of operation than electronic/semiconductor implementations of functionally-similar computational circuits.

Neural networks implemented in photonic systems derive the benefits of optical physics; linear transformation and some matrix operations can be performed entirely in the optical domain. For example, Coriant Technology and Twitter have described optical systems (cf. Yichen Shen et al., “Deep Learning with Coherent Nanophotonic Circuits”, arXiv: 1610.02365 Phys. Op., 7 Oct. 2016) that may achieve high speed of operation and low power consumption.

However, to-date, optics-based implementations of neural network computation circuits are bulky and costly (compared to all-semiconductor implementations) due to the lack of very-small-size low-cost light modulation circuits (which are required to generate signals and perform multiplications), and it is not yet apparent how this basic technological may get resolved.

Therefore, there is a need for improved computational circuits for neural networks and more generally machine learning applications, which combine low cost, small size, high speed of operation, and low power consumption.

### II. Random Projection

Another mathematical technique used to analyze sparse data sets is random projection. It is a different technique than neural networks, but it is applicable to a wide range of machine learning, signal analysis and classification applications. Conceptually, random projection consists in transforming low-dimensionality input data into higher-dimensionality output data, such that the output data can easily be separated (or classified) into their constituent independent components.

As stated above, many types of very large data sets are very sparse in their attribute or feature space. This occurs because it is nearly impossible to obtain a uniform sampling of points along every attribute/feature axis. As a result, in the high-dimensional feature space (generally a Hilbert space), the vectors of very large data sets are distributed very sparsely. Further, Euclidean distances have a reduced significance—the ratio between the largest to the small distance in the feature space goes to 1 as the dimensionality approaches infinity (cf. D. L. Donoho, “High-Dimensional Data Analysis: The Curses and Blessings of Dimensionality,” Lecture on Aug. 8, 2000, to the American Mathematical Society “Math Challenges of the 21st Century”; available from http://www-stat.stanford.edu/˜donoho/, retrieved on Dec. 10, 2016).

Random Projection (RP) and related methods like Principal Component Analysis (PCA) have been in use for decades to reduce the dimensionality of large datasets while still preserving the distance metric (cf. Alireza Sarveniazi, “An Actual Survey of Dimensionality Reduction”, American Journal of Computational Mathematics, 4:55-72, 2014).

The Johnson-Lindenstrauss lemma (cf. W. B. Johnson and J. Lindenstrauss (1984). “Extensions of Lipschitz mappings into a Hilbert space”. In Conference in Modern Analysis and Probability, Contemporary Mathematics. 26:189-206, 1984) forms the basis of random projection. It states that if points in a vector space are of sufficiently high dimension, then they may be projected into a suitable lower-dimensional space in a way which approximately preserves the distances between the points. That is, in random projection, the original d-dimensional data is projected to a k-dimensional (k<<d) subspace, using a random k×d—dimensional matrix.

A somewhat related concept is that of random selection of features (cf. Sachin Mylavarapu and Ata Kaban, “Random projections versus random selection of features for classification of high dimensional data”, Proceedings of the 13th UK Workshop on Computational Intelligence (UKCI), 2013, 9-11 Sept. 2013).

Random projection is traditionally implemented on general-purpose computers, and so suffers from the limitations of common CPU systems: comparatively high power consumption, and a limited speed due to the CPU/DRAM memory bottleneck.

Recently, the company LightON has proposed to use optical processing to perform random projection (cf. A. Saade et al., “Random Projections through multiple optical scattering: Approximating kernels at the speed of light”, Proceedings of the 2016 IEEE International Conference on Acoustics, Speech and Signal Processing (ICASSP), pp. 6215-6219). The projection is achieved by the scattering of laser light in random media. The transmitted light is collected by a camera that records the resulting interference pattern, which forms the output. Such a system would have a high data throughput, but the proposed implementation is large and comparatively costly. Also, the proposed implementation has a fixed (i.e. not programmable and not reconfigurable) response. Improved implementations of random projection are needed.

### III. Reservoir Computing

An alternate mathematical technique to analyze sparse datasets is reservoir computing. Reservoir computing networks are a type of recurrent neural networks, but they are fundamentally different than multi-layer perceptron networks and therefore deserve to be considered as their own class of computing devices. Reservoir computing networks are applicable to a wide range of machine learning, signal analysis and classification applications.

In the context of machine learning, a reservoir is a group of nodes (or neurons), linear or nonlinear, that are interconnected in a network (see, e.g., FIG. 4). The key feature of reservoirs is that their neurons are interconnected randomly and recurrently. The state of the reservoir at a given time are dependent on the inputs, the state of the reservoir (i.e. the reservoir has memory from previous activity), and the configuration of the reservoir. A review of reservoir computing is found in Mantas Lukogevieius and Herbert Jaeger, “Reservoir computing approaches to recurrent neural network training”, Computer Science Review, 3(3): 127-149, August 2009. The randomness and high density of recurrent connections differentiates reservoir computing networks from multi-layer perceptrons and related types of neural networks.

Mathematically, a reservoir can be shown to perform a random projection of its input space onto its output space. A reservoir whose nodes and connections are linear is a linear time-invariant (LTI) system, and therefore can be thought as performing Principle Component Analysis (PCA), which is a linear method of separating data into its components based on its eigenvectors. A reservoir whose nodes or/and connections are non-linear has much richer dynamics than a linear reservoir. Research into nonlinear reservoirs is broadly classified into two areas: Echo State Networks (ESN) and Liquid State Machines (LSM).

When used for a classification application, a reservoir computing device typically has a reservoir and an extra “output layer” of neurons that is fully connected to the reservoir neurons. The weights of the connections between this output layer and the reservoir neurons are selected to perform the desired classification operation. Effectively, the reservoir computes a large variety of non-linear functions of the input data, and the output neurons select those functions that achieve the desired classification operation. Classifiers built on reservoir computing networks have the advantage of being easier to train (i.e. configure) than multi-layer perceptrons and other traditional neural network architectures. For applications that involve the classification of time sequences of data, classifiers built on reservoir computing networks have the advantage of being much easier to train than MLP-type recurrent neural networks.

Reservoir computing networks have been implemented primarily on digital electronic circuits, including general-purpose computers, ASICs, FPGAs and other specialized digital processors. For example, U.S. Pat. No. 7,321,882 (“Method for supervised teaching of a recurrent artificial neural network”) issued to Herbert Jaeger teaches how an ESN can be implemented on digital computers. However, when used for classification applications, this type of implementation involves a massive amount of computations (the state of every neuron in the reservoir must be explicitly computed at every time step) even though a small number of those computations is required to perform the classification task. As a result, digital electronic implementations of reservoir computing networks have comparatively high power consumption. In the present document, when we refer to implementations of reservoir computing networks on digital electronic circuits as digital reservoirs.

Reservoir computing networks have also been implemented using optical techniques, but many such demonstrations use an optical fiber as reservoir (i.e. the reservoir of randomly- and recurrently-connected neurons is replaced by a simple delay line), which reduces the functionality and computational capability of these networks. Other optics-based demonstrations use optical components that are comparatively large and costly. Finally, reservoir computing networks have been implemented using water as reservoir, but such demonstrations do not scale beyond limited proof-of-concept examples.

### BRIEF SUMMARY

Embodiments of the present technology may be directed to an acoustic-wave reservoir computing (AWRC) device that performs computations by random projection. In some embodiments, the AWRC device is used as part of a machine learning system or as part of a more generic signal analysis system. The AWRC device takes in multiple electrical input signals and delivers multiple output signals. It performs computations on these input signals to generate the output signals. It performs the computations using acoustic (or electro-mechanical) components and techniques, rather than using electronic components (such as CMOS logic gates or MOSFET transistors) as is commonly done in digital reservoirs.

One aspect of the present disclosure relates to a wave propagation computing (WPC) device for computing random projections, the WPC device has an analog random projection medium; and a plurality of boundaries that demarcate at least one active region in the medium as one or more cavities; and a plurality of transducers connected to the medium, the plurality of transducers including at least one transducer to convert an electrical input signal into signal waves that propagate in the medium, and the plurality of transducers including at least one transducer to convert the signal waves that propagate in the medium into an electrical output signal.

In some embodiments, the medium has asymmetric geometric boundaries. In some embodiments, the medium provides non-linear propagation of the signal waves. In some embodiments, the medium provides a multi-resonant frequency response over at least one decade in frequency. In some embodiments, the medium has a piezoelectric material. In some embodiments, the medium has a thin-film piezoelectric material. In some embodiments, the medium has internal and/or external impedance discontinuities. In some embodiments, the impedance discontinuities are one or more of structure and material discontinuities. In some embodiments, the medium has one or more of a through hole, a partial hole, a local thickness increase, or a particulate/material inclusion. In some embodiments, the medium has two or more mediums. In some embodiments, the medium is demarcated by a plurality of surfaces to reflect the signal waves, the plurality of surfaces forming a three-dimensional structure. In some embodiments, the medium has a tunable propagation medium with one or more material properties that can be altered after manufacturing in a repeatable manner. In some embodiments, the material properties are one or more of a coefficient of a stiffness matrix, a modulus of elasticity, a Poisson ratio, or a wave velocity. In some embodiments, the material properties can be altered by the application of an electric field.

In some embodiments, a transducer of the plurality of transducers provides a non-linear electrical output signal. In some embodiments, a transducer of the plurality of transducers is a microelectromechanical systems (MEMS) device. In some embodiments, at least two of the transducers are electrically connected via an optional external circuit to form a feedback path. In some embodiments, at least two of the transducers are electrically connected via an optional external circuit to form a self-test path. In some embodiments, the transducers are positioned along a lateral periphery of the medium. In some embodiments, a transducer is positioned within an interior of the medium. In some embodiments, the transducers are positioned across a surface of the medium.

In some embodiments, the signal waves are acoustic waves. In some embodiments, the signal waves are elasto-acoustic waves. In some embodiments, the signal waves are electromagnetic waves.

In some embodiments, the WPC device further has a substrate and a suspension structure connecting the cavity to the substrate, wherein the suspension structure isolates the cavity from the environment. In some embodiments, the medium is formed by a Micro-Electro-Mechanical Systems (MEMS) thin-film structure.

Another aspect of the present disclosure relates to a compound WPC device having two or more WPC devices and an interconnect architecture connecting the two or more of the WPC devices. In some embodiments, the interconnect architecture is a MEMS structure. In some embodiments, the interconnect architecture is a circuit. For example, the compound WPC device and be configured to operate on different portions of a data sample simultaneously, or on multiple data samples simultaneously, or any combination thereof. The interconnect architecture is configurable by the skilled person to achieve device performance objectives.

Yet another aspect of the present disclosure relates to a method for performing computations with an analog random projection device, the method includes: sending a plurality of electrical input signals to a plurality of input transducers connected to an analog random projection device, wherein the input transducers convert the electrical input signals into signal waves to propagate in a medium of the analog random projection device; physically propagating the signal waves within the medium; and receiving a plurality of electrical output signals from a plurality of output transducers connected to the medium, wherein the output transducers generate the electrical output signals from the signal waves that propagate in the medium.

In some embodiments, the method further includes processing the electrical signals to perform any one or more of signal processing and machine learning. In some embodiments, the method further includes processing the electrical output signals to perform one or more signal processing or machine learning operations. In some embodiments, the medium has an asymmetric geometry. In some embodiments, the medium has impedance discontinuities. In some embodiments, at least two of the transducers are electrically connected to form a feedback path.

### BRIEF DESCRIPTION OF DRAWINGS

FIG. 1 is a plot of Moore's Law that shows the growth in the number of transistors per function over time.

FIG. 2 is a diagram that depicts a simple feed-forward neural network from the prior art.

FIG. 3 is a diagram that depicts a simple recurrent neural network from the prior art.

FIG. 4 is a diagram that depicts a simple reservoir neural network from the prior art.

FIG. 5 is diagram that depicts a single degree-of-freedom mechanical system.

FIG. 6 is graph representation of the mechanical system from FIG. 5.

FIG. 7A is a diagram that depicts a continuous medium and its finite element representation.

FIG. 7B is a diagram that depicts the finite element representation from FIG. 7A, showing two possible energy-transfer paths from input to output.

FIG. 8 is a diagram that depicts an electromechanical reservoir.

FIG. 9 is a diagram that depicts an electromechanical reservoir with features that enable random projection computation.

FIGS. 10A-10H are diagrams that depict the operation of an acoustic wave reservoir computing device.

FIG. 11 is a diagram that depicts another possible method by which a method by which input data can be fed into a reservoir.

FIG. 12 is a diagram that depicts a finite-element solid model of a preferred embodiment of a reservoir where the cavity is surrounded by piezoelectric TE-mode transducers.

FIG. 13 is a diagram that depicts a finite-element solid model of an alternate embodiment of a reservoir where the cavity is surrounded by piezoelectric LE- or contour-mode transducers.

FIG. 14 is a diagram that depicts a cross-section of the embodiments presented FIGS. 12 and 13.

FIG. 15 is a diagram that depicts a finite-element solid model of an alternate embodiment of a reservoir that is similar to the embodiment of FIG. 12, in top view.

FIG. 16 is a diagram that depicts the finite-element solid model presented on FIG. 15, seen at an angle from the bottom.

FIG. 17 is a diagram that depicts the finite-element solid model presented on FIG. 16, seen at an angle from the bottom and zoomed in on transducer elements that are placed on the bottom side of the reservoir

FIG. 18 is a diagram that depicts a cross-section of the embodiment presented on FIG. 15.

FIG. 19 is a diagram that depicts of an alternate embodiment of the reservoir, in which TE-mode transducers are located above or below the cavity.

FIG. 20 is a diagram that depicts a cross-section of the embodiment of FIG. 19.

FIG. 21 is a Scanning-Electron Microscope (SEM) image of a test structure for a TE-mode transducer, from the embodiment of FIG. 19.

FIG. 22 is a SEM image of a group of transducers from the embodiment of FIG. 19. The cavity is not present in this die image.

FIG. 23 is a diagram that depicts a group of reservoirs that are composed to form a compound reservoir.

FIGS. 24A-24D are diagrams that depict a finite-element solid model of an alternate embodiment of a reservoir where the input port transducers are located on top of the cavity and feed the input signals from the top.

FIG. 24E is a simplified and idealized diagram of the solid model depicted on FIGS. 24A-24D, showing a possible operating mode of the embodiment for image analysis.

FIG. 24F is a simplified and idealized diagram of the solid model depicted on FIGS. 24A through 24D, showing a possible operating mode of the embodiment for the analysis of video frames.

FIGS. 25A-25C are diagrams that depict a finite-element solid model of an alternate embodiment of a reservoir, where one or more LE-mode transducer pairs are configured to generate rotational waves.

FIG. 25D is a diagram of two transducers combined to form a single rotational transducer.

FIG. 25E is a diagram that depicts an example of a particular order of electrode stimulation of the rotational transducer of FIG. 25D, in order to launch a torsional wave into the cavity.

FIG. 25F is a diagram that depicts the rotational strain wave that results from the application of the stimulus shown on FIG. 25E.

FIG. 26 is a diagram that depicts a reservoir that is connected to one of more sensors.

FIG. 27 is a diagram that depicts a reservoir, whereon the reservoir cavity can also perform sensing functions.

### DETAILED DESCRIPTION

Embodiments of the present disclosure are described in detail with reference to the drawing figures wherein like reference numerals identify similar or identical elements. It is to be understood that the disclosed embodiments are merely examples of the disclosure, which may be embodied in various forms. Well-known functions or constructions are not described in detail to avoid obscuring the present disclosure in unnecessary detail. Therefore, specific structural and functional details disclosed herein are not to be interpreted as limiting, but merely as a basis for the claims and as a representative basis for teaching one skilled in the art to variously employ the present disclosure in virtually any appropriately detailed structure.

In the following, we describe acoustic (or elastic, or electro-mechanical) reservoirs, but one skilled in the art will understand that these descriptions apply equally to other types of physical reservoirs based on electromagnetic, thermomechanical, diffusion, or other physical operating principles whereby waves can propagate in a cavity demarcated by boundary conditions. For example, an electromagnetic reservoir can be designed and fabricated to exhibit a response similar to that of the AWRC device, and therefore can be exploited for the high-dimensional projection of input data. As used herein, propagation of signal waves in such devices may be understood to constitute any of dispersal, radiating, scattering and/or broadcasting of the signal waves. In this document, the word “acoustic” and the word “elasto-acoustic” are used. In physical systems, “acoustic” may imply waves in air/gas, i.e. sound, whereas “elasto-acoustic” may imply waves in solid/liquid material/medium. In this document and depending on it context, use of the phrase “acoustic” may be generally understood to concern “elasto-acoustic” and, in particular, the propagation of waves within a solid and/or liquid medium. Nevertheless, the present technology may also be applied with devices that propagate waves in an air/gas as in sound waves.

### I. Brief Overview of AWRC Devices

### A. Structure

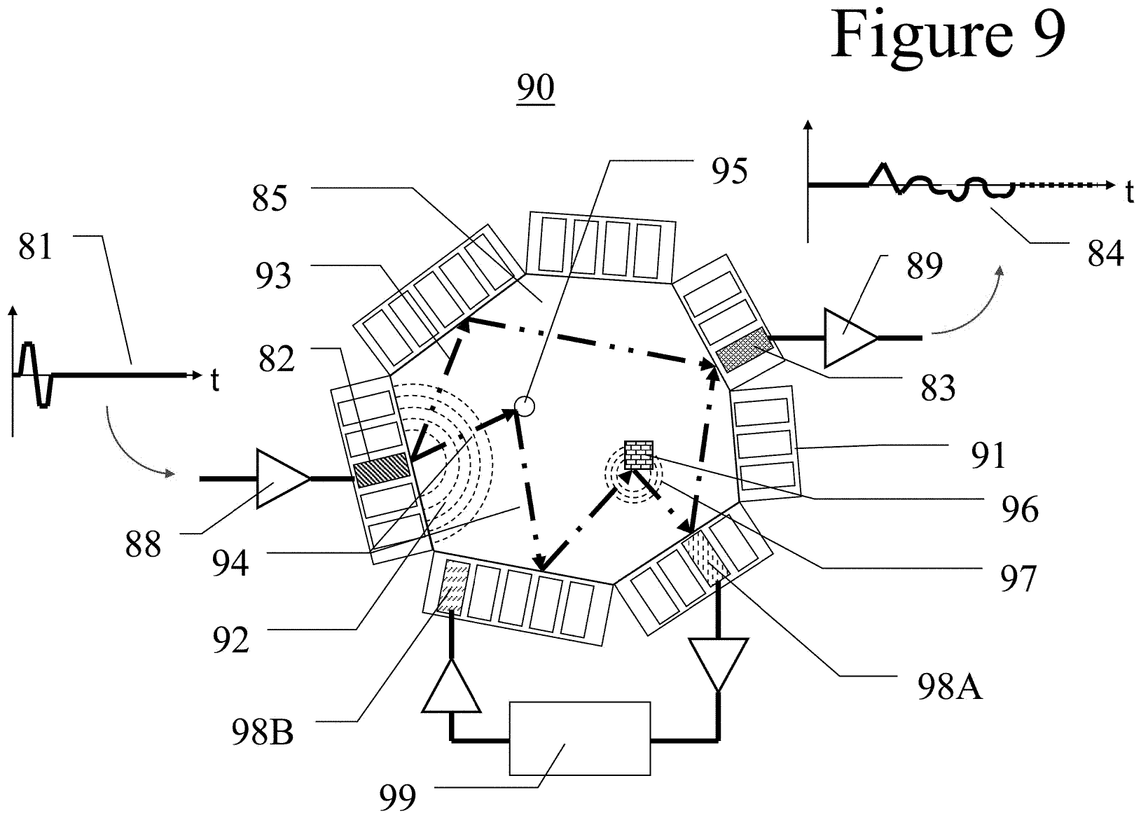

As shown in FIG. 9, an AWRC device may include an acoustic cavity, input transducers and output transducers.

The acoustic cavity 85 may be made of a material (or propagation medium) that supports the propagation of acoustic waves (e.g. 92 and 97). Acoustic waves are also called elasto-acoustic waves or elastic waves. The cavity may be designed such that waves reflect at impedance discontinuities located at the outer boundaries of the cavity, as well as at impedance discontinuities deliberately located within the cavity, e.g. 95 and 96. Such reflections 97 yield multiple wave propagation paths (e.g. 93 and 94) between the input transducers (e.g. 82) and the output transducers (e.g. 83). The reflections, as well as wave dispersion, mode conversion, reservoir tuning, the use of a non-linear propagation medium, the appropriate selection of transducer location, etc. contribute to achieving a rich dynamic response.

As shown in FIG. 9, the input transducers (e.g. 82) convert the electrical input signals (e.g. 81) to acoustic waves (e.g. 92). The input transducers are acoustically connected to the cavity such that acoustic waves generated by the transducers are coupled into the cavity. The generated waves propagate in the cavity, and are reflected and transformed at outer boundaries of the cavity and at inner impedance discontinuities (e.g. 95 and 96). The waves generated at input transducers propagate along multiple paths (e.g. 93 and 94).

As shown in FIG. 9, the output transducers (e.g. 83) convert acoustic waves to the electrical output signals (e.g. 84). The output transducers are acoustically connected to cavity such that acoustic waves propagating in the cavity are coupled to the transducers. In other terms, the output transducers read out the state of the wave at specific locations of the cavity.

The AWRC device can also include electronic circuits, such as input interface circuits (e.g. 88) that drive the input transducers, or/and output interface circuits (e.g. 89) that amplify the low-level generated by the output transducers. These circuits can be linear or non-linear, and they can substantially affect the overall functionality or response of the AWRC device, as is readily appreciated by one skilled in the art. In addition, the AWRC device can include other circuits, such as to establish feedback loops around the reservoir (e.g. 99).

### B. Operation

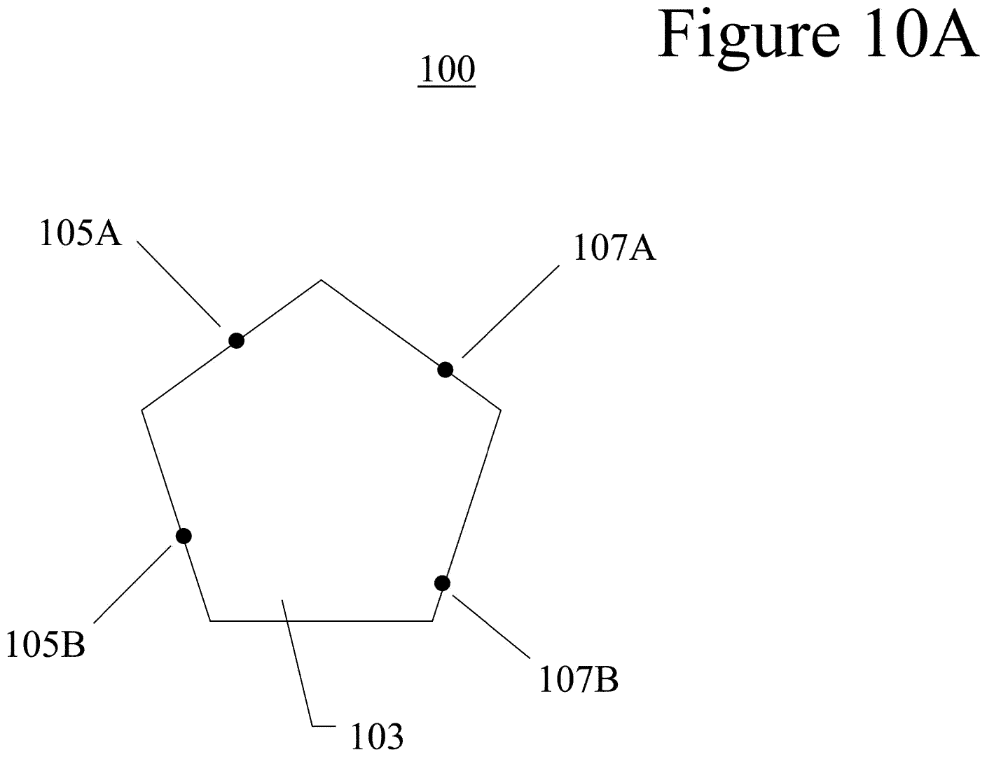

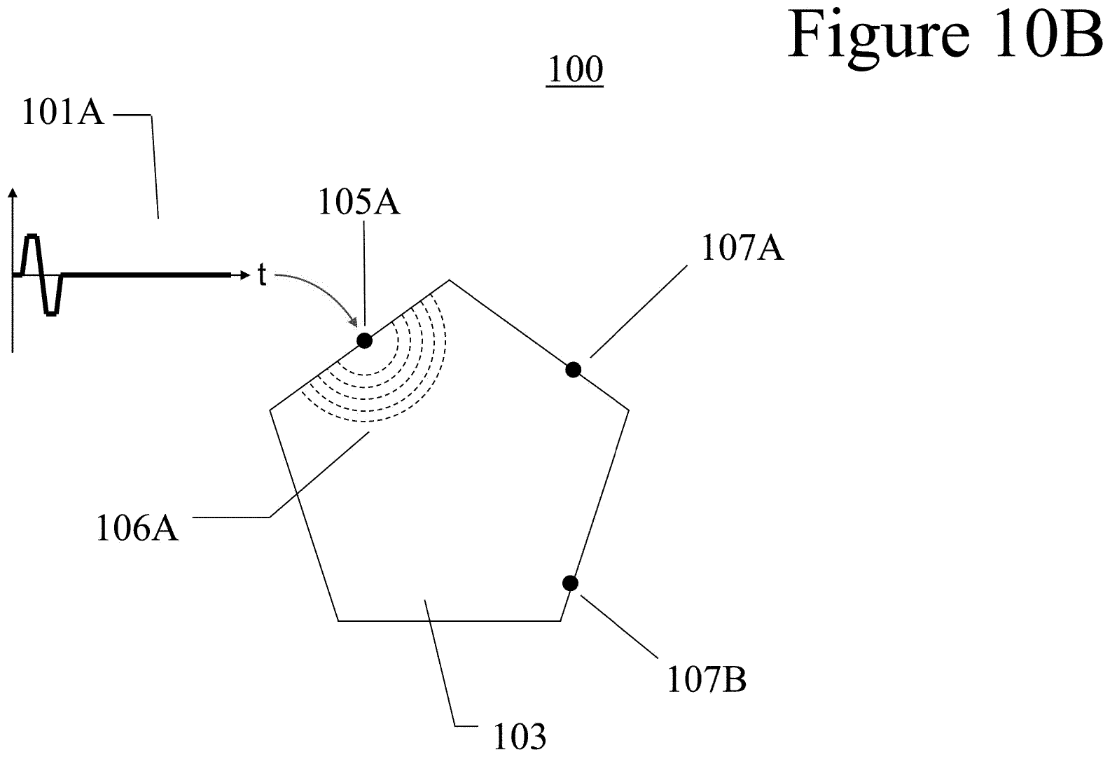

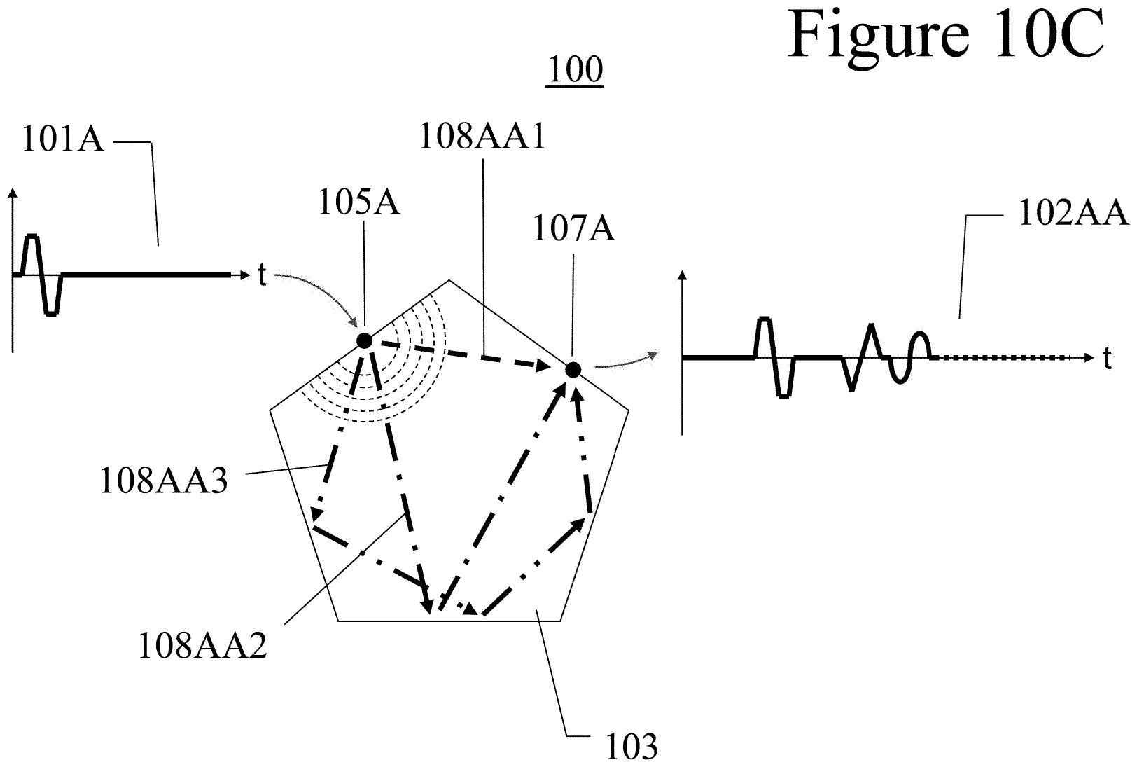

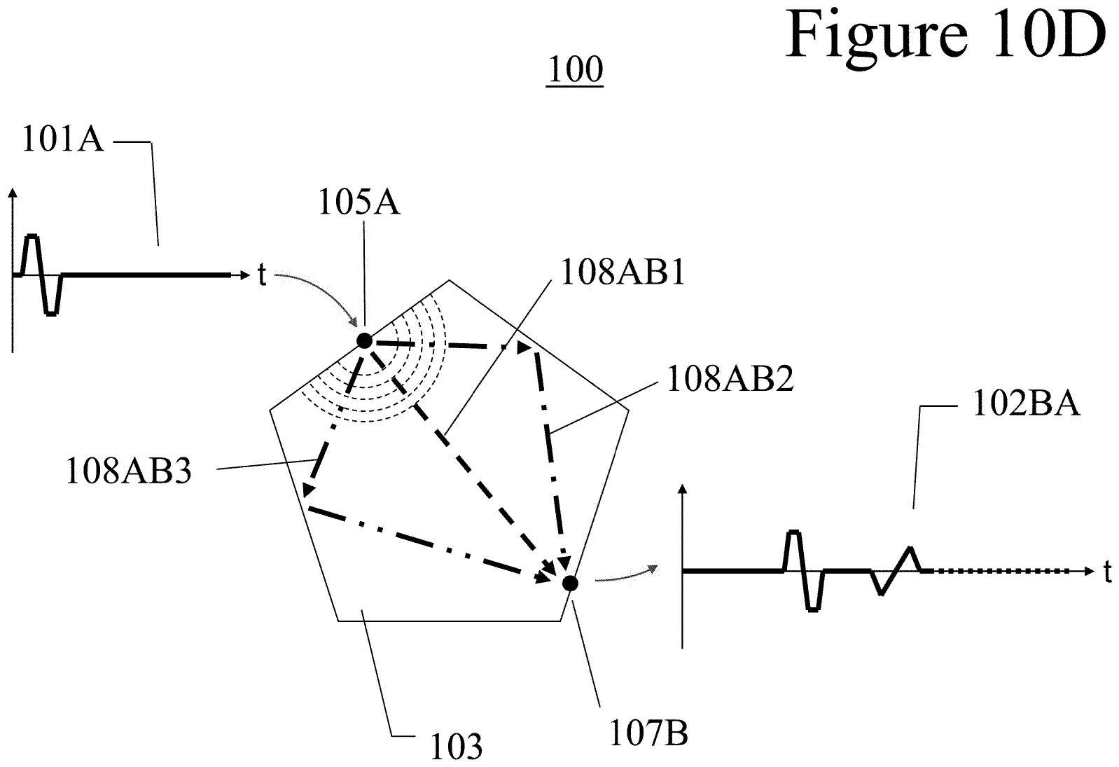

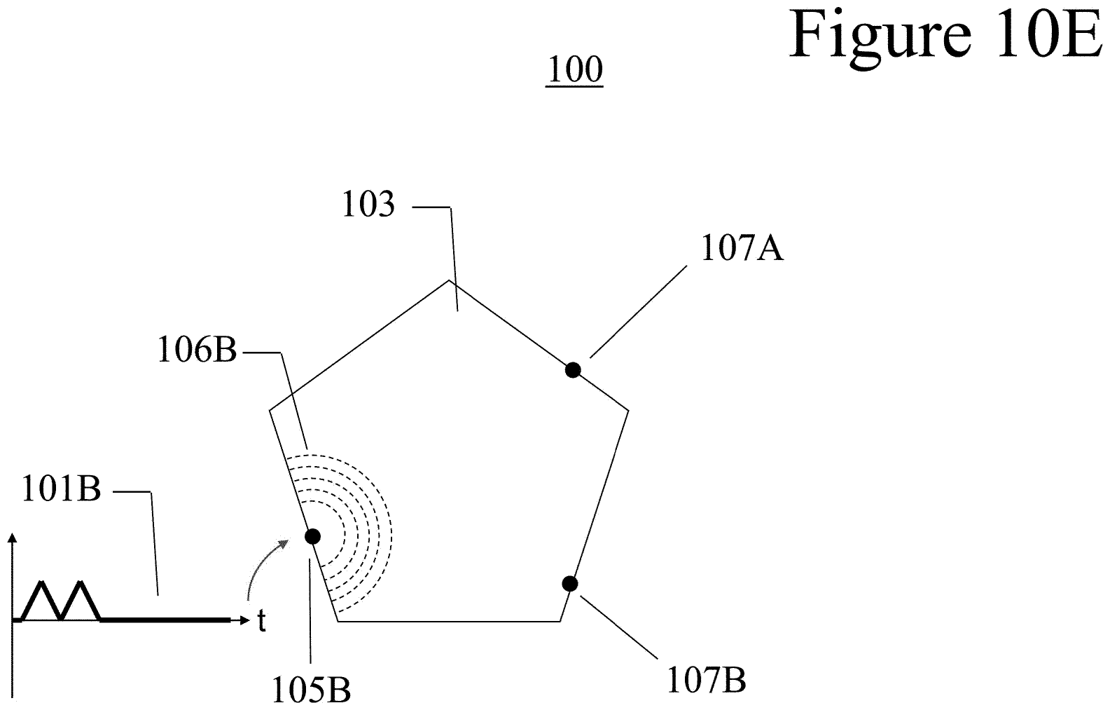

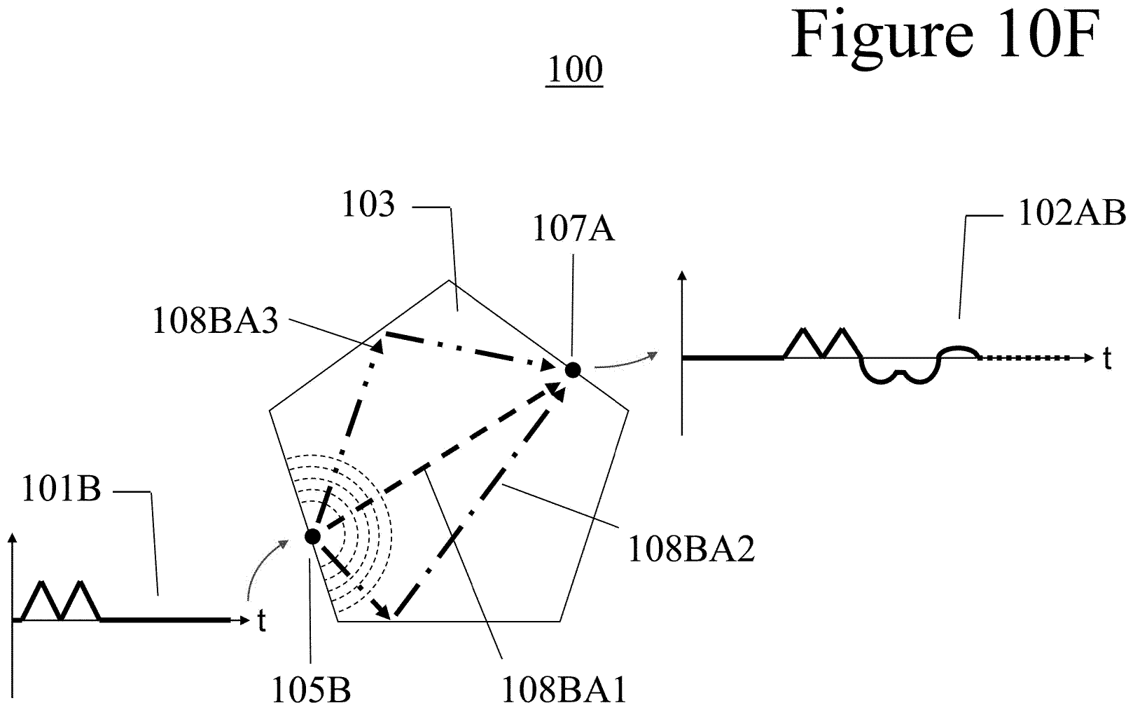

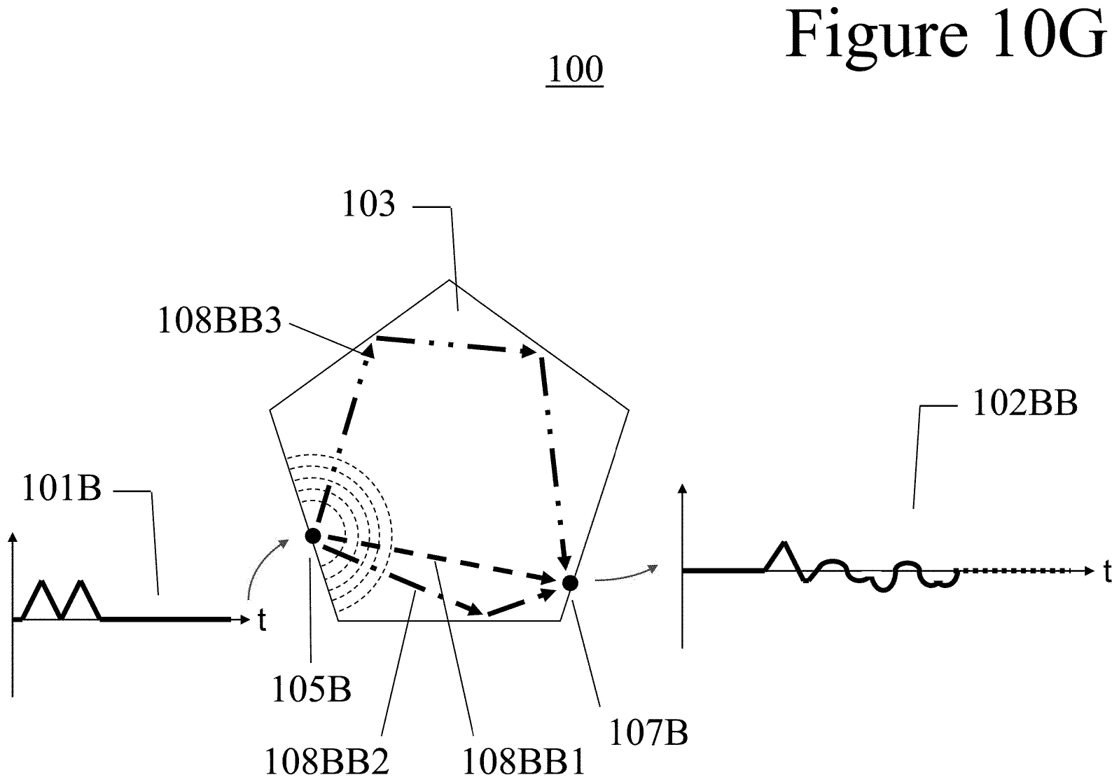

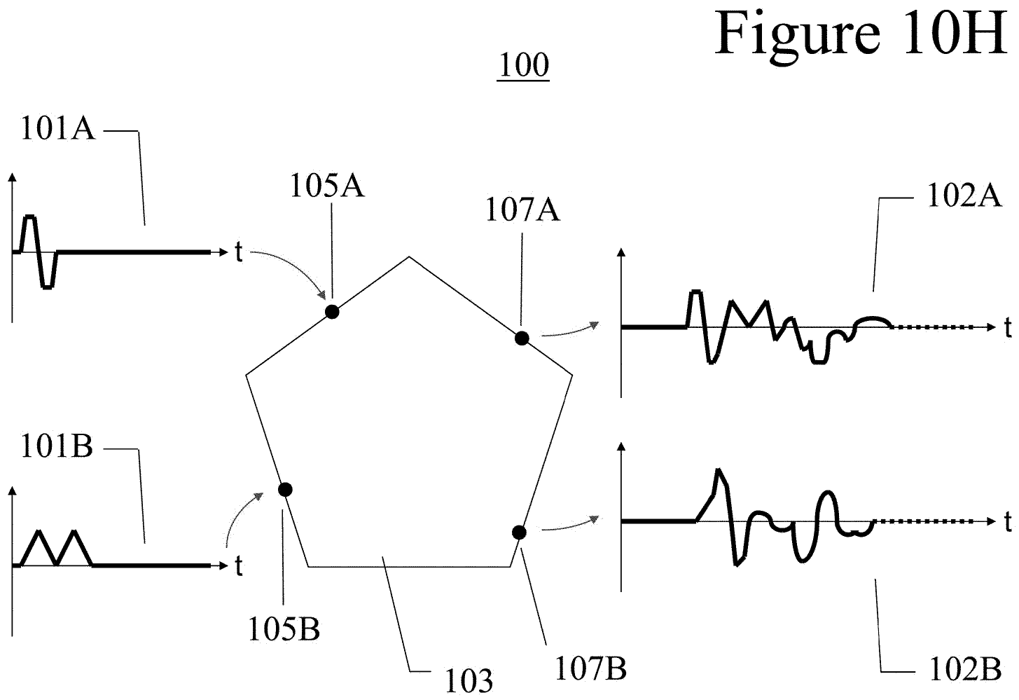

One method of operation of an AWRC device is depicted in FIGS. 10A-10H for a very simplified reservoir. As depicted on FIG. 10A, the cavity 103 has a simplified cavity shape, no impedance discontinuity located inside the cavity, only two input transducers (105A and 105B) and only two output transducers (107A and 107B).

As depicted in FIG. 10B, the input signal 101A is applied to the input transducer 105A, which induces acoustic wave 106A in the cavity 103. The acoustic wave 106A propagates through the cavity, radially at first. When part of wave 106A reaches a boundary, it reflects; as multiple parts of wave 106A reach different boundaries, wave 106A effectively splits into multiple waves that each takes a different direction of propagation. Three propagation paths from input transducer 105A to output transducer 107A are depicted on FIG. 10C: a direct path 108AA1, and two paths 108AA2 and 108AA3 that involve at least one reflection. The output transducer 107A responds to the acoustic waves that reach it, and generates output signals 102AA.

Likewise, the acoustic wave 106A propagates through the cavity, reflects at the outer boundaries of the cavity, and reaches output transducer 107B via multiple propagation paths, as depicted on FIG. 10D. The output transducer 107B responds to the impinging acoustic waves, and generates output signals 102BA

In FIGS. 10C and 10D, input signal 101A is depicted as a single bipolar pulse, so the multiple waves that reach the output transducers each induce a pulse-like “echo” on the output signals. The “echo” induced by the wave that propagates through the direct path arrives first and is the least distorted. The “echoes” induced by the waves that propagate through the longer and indirect paths arrive later and are more distorted. On FIGS. 10C and 10D, the illustrations of the output signals are truncated in time and their shape is conceptual, for clarity.

In some applications of the AWRC device, the input signals may be more complex than depicted here, so the output signals may be much more complex as well. In addition, in some AWRC devices, impedance discontinuities may be incorporated into the cavities, so many more paths of propagation may exist. Also, in some AWRC device, the propagation waves undergo dispersion, mode conversion, attenuation, and other linear and non-linear transformations, which are not depicted in FIGS. 10A-10H.

FIGS. 10E-10G depict the operation of the AWRC device when signal 101B is applied to input transducer 105B: the wave 106B generated by input transducer 105B cause output transducers 107A and 107B to generate output signals 102AB and 102BB. All explanations provided for FIGS. 10B-10D also apply to FIGS. 10E-10G.

In some applications, input signals 101A and 101B may be applied simultaneously to input transducers 105A and 105B, so the waves 106A and 106B generated by input transducers 105A and 105B propagate simultaneously in the cavity 103 and combine to yield output signals 102A and 102B, as depicted on FIG. 10H. If the cavity is purely linear, output signal 102A is the sum of signals 102AA and 102AB, and output signal 102B is the sum of signals 102BA and 102BB. However, it is often beneficial to have rich dynamics, so for such a benefit the cavity and reservoir may be non-linear, such that the waves generated by the multiple input transducers combine non-linearly in the cavity, and yield output signals that are complex functions of the input signals.

AWRC devices can perform random projection on any data that can be encoded into a time series. This includes, without limitation, speech processing, image and video classification, sequence-to-sequence learning, autoencoders, and sensor data fusion applications.

Note that, depending on the nature of the data and the application of the AWRC device, the output signals can be read from the output transducers simultaneously with the input signals being applied to the input transducers, or after some delay after the input signals have been applied to the input transducers. For example, for applications that involve a continuous input data stream (that is, input data that is continuous over time, or continuous over a duration that is much longer than the memory duration of the AWRC device), such as when an AWRC device is used to detect a pattern in a continuous sensor data feed, the input signals are applied to the input transducers continuously, and the output signals are read from the output transducers simultaneously, or after a brief delay after the input data have started to be applied to the input transducers, to allow the acoustic waves to propagate in the cavity. Alternately, for example, for applications that involve discrete input data sets (that is, input data that is applied to the input transducers in a time comparable to or shorter than the memory duration of the AWRC device), such as when an AWRC device is used to detect a pattern in data sets generated by different sensors (so each data set is discrete, as defined above), in a first time the input signals are applied to the input transducers, then in a second time the acoustic waves are allowed to propagate in the cavity (and, optionally, feedback is applied, as described below), then in a third time the output signals are read from output transducers, then in a fourth time the acoustic waves are allowed to dissipate so the reservoir can return to a quiescent state before the next input data set is applied.

Note also that AWRC devices are not Turing machines because their operation is not defined by a sequential algorithm. In addition, they do not implement a von-Neumann computing architecture, because there is no separation between the “program” and the data.

### C. Randomness

A desirable characteristic of the response of an AWRC device is its randomness. Excluding random noise, the response of AWRC devices is deterministic. However, the response of any given AWRC device is random in the sense that it is difficult to ascertain accurately except by direct measurement. Thus, the response of AWRC devices is pseudo-random. The response is highly complex (as discussed below) and it is determined by the shape of the cavity, the location of impedance discontinuities within the cavity, the location of the input and output transducers, etc. The pseudo-random response of an AWRC device can be changed by varying its cavity shape, the location of impedance discontinuities within its cavity, the location of its input and output transducers, etc.

To provide an extra degree of pseudo-randomness, it is also possible to randomly assign the device's input and output signals to the reservoir's input and output transducers.

In addition, the pseudo-random nature of AWRC devices can be enhanced by deliberately allowing random defects to be built in the cavity during manufacturing. Such defects can include material discontinuities, particulate inclusions, vacancies, etc. The defects induce impedance discontinuities, which in turn cause wave reflection, wave dispersion, mode conversion, etc.

In addition, for applications where true randomness is required, the amplitude of the input signals can be decreased until noise generated by the cavity, the input transducers or the output transducers yields the desired signal-to-noise ratio.

### D. Dimensionality

Another desirable characteristic of the response of an AWRC device is its dimensionality. A high-dimension response is often preferred for random projection operations. As used herein, an AWRC device with a high-dimension response has a rich dynamic response. The richness of the reservoir dynamics depends on the number of modes that are stimulated by the applied input signals.

To achieve a rich dynamic response, a cavity may be designed to achieve a proper tradeoff between number of modes and quality factor (Q). At one extreme, a cavity could support a single mode (i.e., the cavity would behave like a single-mode transmission line or a single-mode resonator) with very high quality factor. At the another extreme, a cavity could support thousands of modes, with each mode having a very low Q. At either extremum, the input signals would not be projected to a sufficiently number of usable dimensions for random projection. Therefore, it is desirable to design the AWRC device reservoir to operate within these extrema so as to achieve a rich dynamic response. Design methods that achieve a suitably rich dynamic response are discussed below.

### E. Some Distinctions from Digital Reservoirs

In a physical reservoir, a material element (e.g. an atom of the propagation medium) is connected locally to neighboring material elements in the cavity. Thus, the projection matrix of an AWRC device has fixed local connectivity, whereas the projection matrix of a digital reservoir (e.g. an Echo State Network) has global connectivity (i.e. every node of the reservoir is connected to every other node).

In addition, the input and output transducers (i.e. the input and output ports) of a AWRC device are connected to select locations of the cavity (where the transducers are physically located), whereas the input and output ports of a digital reservoir are connected to every node in the reservoir. The limited connectivity of AWRC device input and output transducers can achieve a form of dropout.

Further, the cavity of a AWRC device may not have gain, so its response may be intrinsically dissipative and bounded, whereas the spectral radius of the connection matrix of digital reservoirs must be normalized to ensure that the response of the reservoir does not diverge. An additional benefit of the finite quality factor of the cavity of an AWRC device is that the reservoir noise can perform L2 regularization.

### II. Random Projection in an AWRC Device

An AWRC device can perform (1) the random projections of the input space onto a higher-dimensional space, followed by (2) a random projection onto the output space. As a consequence, the outputs are a frame of the inputs (as described above).

Physical systems such as an acoustic-wave reservoir have finite energy, therefore the signals that are generated, propagated, dissipated, reflected and received within a physical system all have finite energy. All the possible signals form a special Hilbert space called an [symbol] 2 space, or Signal Space. Signal Space can be spanned by an orthonormal basis formed by the coefficients of a Fourier series. However using an orthonormal basis is not always preferred. Sometimes the noise in the signal or signal loss causes the basis to cease being orthonormal. Therefore, in the signal processing state of the art, “frames” (cf. Jelena Kovacevic and Amina Chebira, “An Introduction to Frames”, Foundations and Trends in Signal Processing, 2(1):1-94, 2008) are used. Frames are a set of vectors that do not form an orthonormal basis. Since the frame is not an orthonormal basis, a vector in the space can be represented in more than one way. This redundancy allows for fault tolerance and noise mitigation (cf. Stephane Mallat, A Wavelet Tour of Signal Processing, Third Edition: The Sparse Way, Academic Press, Dec. 25, 2008). This is a key advantage of using acoustic wave reservoirs to perform random projection. It is possible to select a frame that spans the Signal Space using methods known by those skilled in the art.

Consider what happens when a signal is injected into a physical reservoir, such as an electromechanical reservoir, via one or more input transducers. The injected signal stimulates one or more modes of the reservoir. The elastic wave propagates through the reservoir—in the bulk and/or the surface of the material. At internal or external impedance discontinuities, the wave is simultaneously reflected and transmitted. The amount of reflection and transmission depends on the impedance mismatch at the interface. In addition, wave propagation causes the generation of secondary waves that propagate along other directions, as a consequence of off-axis elements in the stiffness matrix.

The wave is received at one or more output transducers. The signals read out by the output transducers are linear combinations of the input signals. Thus, the outputs are not single Fourier series components. Rather, they are frames forming a (non-orthonormal) basis of the Signal Space.

Let xⱼ, j=1 . . . M be the inputs to the electromechanical reservoir. Let yᵢ, j=1 . . . N be the outputs from the reservoir. Then, the Fourier expansion of the inputs are of the form:

$${x}_{j} ( t ) = {\sum }_{k} {a}_{k} {e}^{i {ω}_{k} t}$$

where coefficients aₖ are the coefficients of the complex frequency components ωₖ of the reservoir. A similar expansion can be written down for the outputs yᵢ. However, the coefficients of the terms in yᵢ would be redundant linear combinations of the corresponding coefficients in xᵢ (i.e. a Frame):

$${y}_{j} ( t ) = {\sum }_{k} {b}_{k} {e}^{i {ω}_{k} t} and$$

$${b}_{k} = {\sum }_{j} {c}_{j} {a}_{j}$$

where coefficients bₖ are not necessarily equal to aₖ, and coefficients cⱼ describe a (possible non-unique) relationship between the frame bases and the orthonormal input bases. The set of coefficients bₖ form the frame for that particular output yⱼ. Note that frequency components in a particular output are repeated across multiple outputs. Taken together, the outputs are a redundant representation of the input space, i.e. a “cluster ensemble” (cf. X.Z.F ern and C.Brodley, “Random projection for high dimensional data clustering: A cluster ensemble approach”, Proceedings of the Twentieth International Conference of Machine Learning, 2003).

A frame is more formally defined as the set of vectors F= [symbol] fᵢ [symbol] where there exist constants A and B, 0<A≤B<∝ such that:

$$A {‖ x ‖}^{2} \leq {\sum }_{i ∈ I} {\vert 〈 x , {f}_{i} 〉 \vert}^{2} \leq B {‖ x ‖}^{2}$$

for every vector x in the Hilbert space.

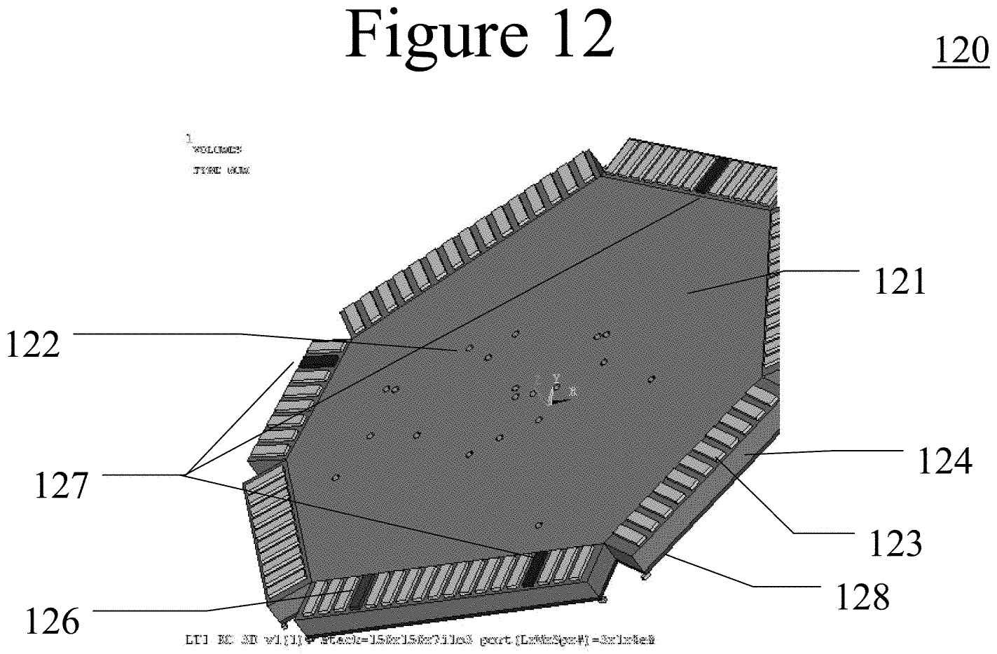

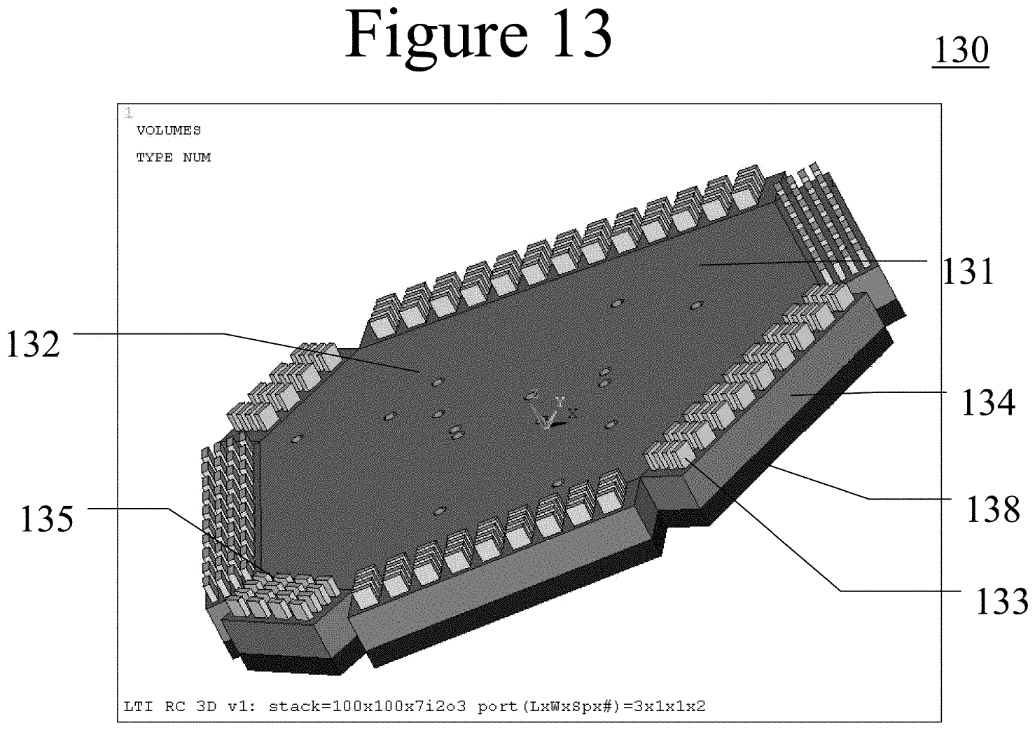

In the embodiment of the Acoustic Wave Reservoir Computing depicted on FIGS. 12 and 13, the outputs are positioned at the periphery of the reservoir. By selecting randomly the positions of the outputs from a set of possible output ports, the constructed cluster ensemble is pseudo-random (cf. T. K. Ho, “The Random Subspace Method for Constructing Decision Forests”, IEEE Transactions On Pattern Analysis And Machine Intelligence, 20(8), August 1998).

### III. Physical Structure of an AWRC Device

As mentioned above, FIG. 9 depicts an embodiment of an AWRC device. The AWRC device may have a physical cavity, input transducers, and output transducers. In addition, the AWRC device may include a cavity suspension structure, and feedback or self-test paths. Connections to and from the device are not shown in FIG. 9.

### A. The Cavity

Signals are carried in the AWRC device of FIG. 9 by propagating (or traveling) acoustic (or elastic) waves (e.g. 92, 97) that propagate in the cavity 85. The cavity is a physical body that supports acoustic wave propagation. It is demarcated by boundary conditions that provide impedance discontinuities. Boundaries are located at the outer periphery of the cavity as well as within the cavity, as described below. The elastic waves that propagate in the cavity reflect at impedance discontinuities.

In this document, a thin-film piezoelectric cavity is depicted in many of the figures. However, it is readily understood that a cavity can be designed to operate based on electromagnetic, thermomechanical, diffusion, or other physical operating principles. Further, the cavity can have a full 3D shape.

### 1. Lamb and Shear-Horizontal (SH) Modes

Signals are carried in the cavity by Lamb waves and Shear-Horizontal waves. The elastic wave equation describes the displacement of a wave in terms of spatial coordinates x and time t:

$$\frac{{\partial }^{2} x}{\partial {t}^{2}} = {c}^{2} {∇}^{2} x$$

where c is the propagation velocity and ∇ is the Laplace operator over the spatial coordinates x.

Lamb waves are elastic waves in a plate. Their particle motion lies in the plane that contains the direction of wave propagation and the plate normal. They are guided waves because they are constrained by the geometry of the media in which they propagate. In an infinite solid plate of thickness d, the sinusoidal solutions of the elastic wave equation are of the form:

u=Aₓ(z)·e^{i(ωt-kx)}

v=A_{z}(z)·e^{i(ωt-kx)}

where <u, v> represent the x- and z-axis displacements, ω is the angular frequency, k is the wavevector and A( ) is the amplitude. The wave propagates along the x-axis with a frequency of ω/2π. Lamb waves therefore have no motion in the y-direction. Motion in the y-direction is caused by Shear-Horizontal (SH) waves which, together with Lamb waves, can propagate with straight wave fronts.

Two important modes, S0 and A0, are noted here for their ability to exist over the entire frequency spectrum. They are also called the Extensional mode and Flexural mode, respectively. The AWRC device makes use of both of these modes for operation. However, it is understood by one skilled in the art that higher-order modes exist and can be adapted for use in such devices.

### 2. Rotational Traveling Waves

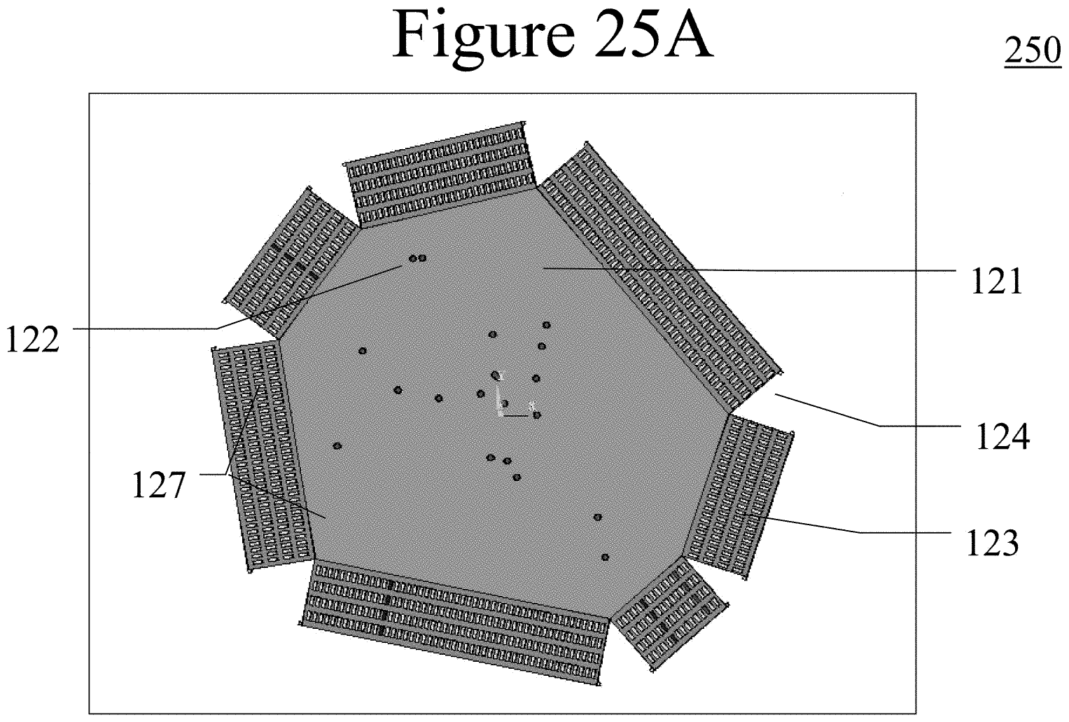

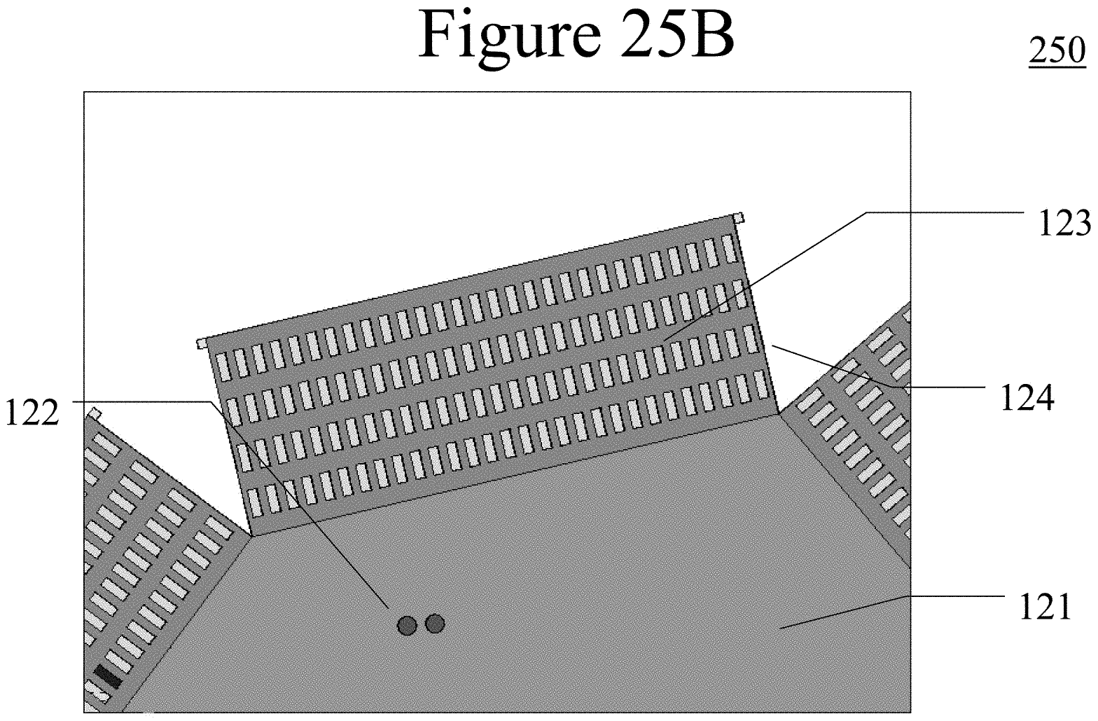

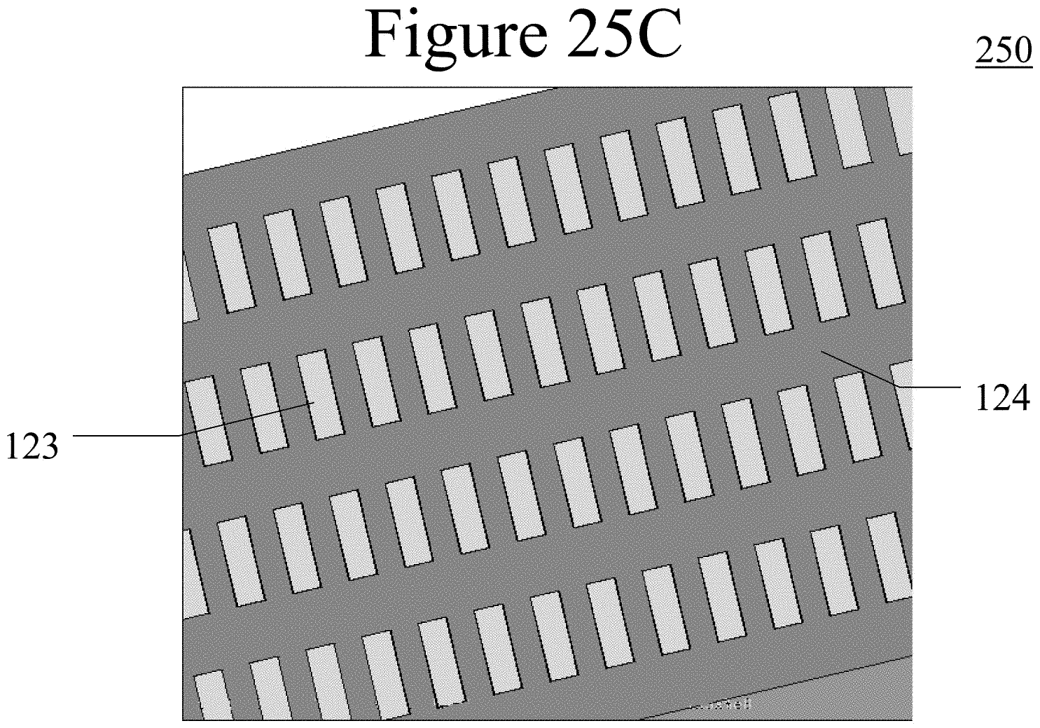

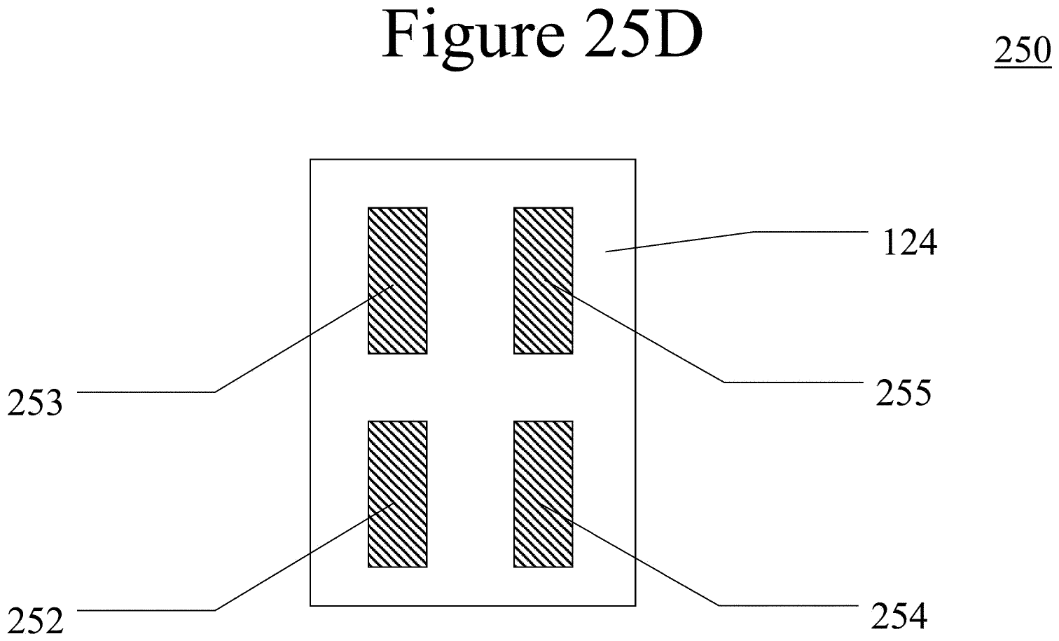

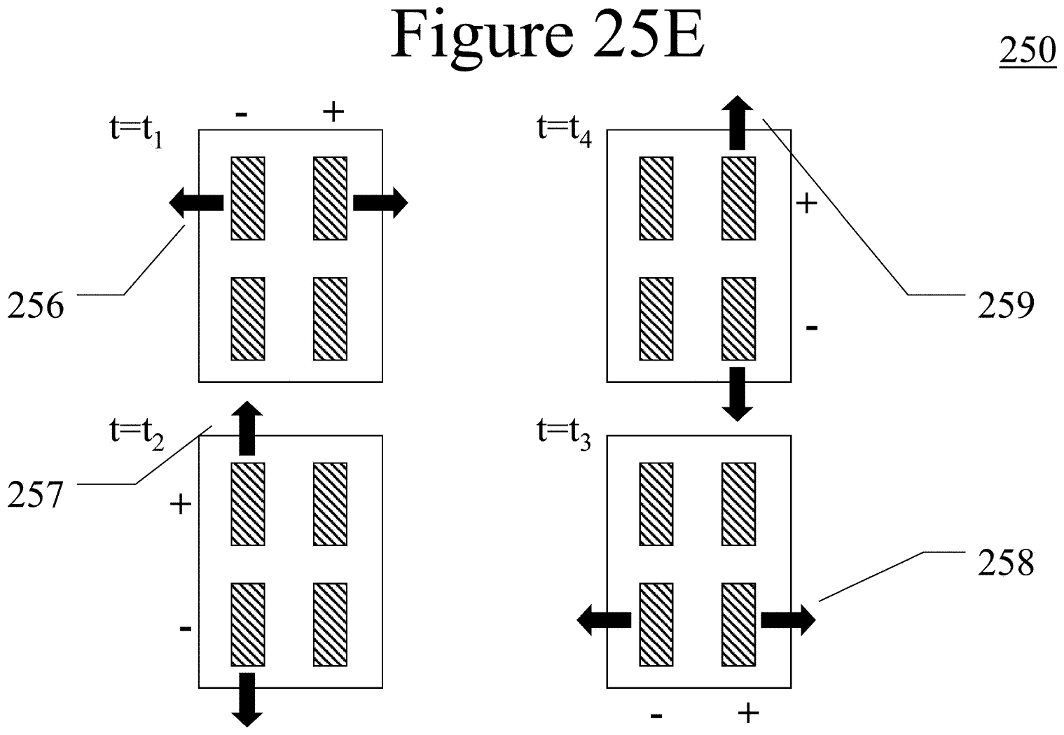

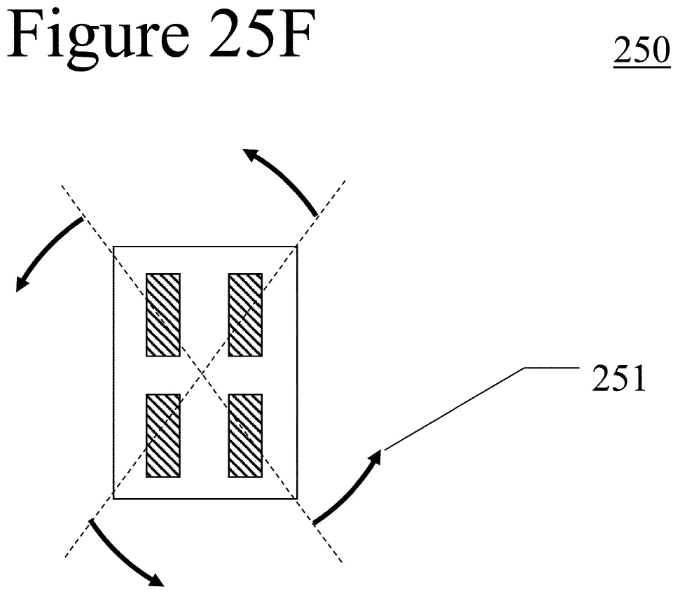

An AWRC device can be designed to use other waves than the laterally-propagating waves discussed above. Conventional elastic theory makes an assumption of infinitesimally small rotational gradients at each material point. Allowing for non-zero rotations adds geometric (kinematic) nonlinearity into the elastic behavior of the cavity. A properly configured transducer can launch or sense such rotational traveling waves, as depicted on FIGS. 25A-25F.

3. Size of the Cavity

The dimensions of the cavity, along with the acoustic properties of the cavity material, determine its memory duration of an AWRC device, i.e. how long the input signals are remembered (just as a memory of a transmission line increase with its length) and projected. The reservoir may be large enough to accommodate all the inputs (if those are applied over a period of time) and outputs (if those are read out over a period of time), while simultaneously not being so large that the signals attenuate excessively before the computation is complete. Manufacturing considerations have an effect on the bounds on the cavity size.

### 4. Shape of the Cavity

An AWRC device may achieve a rich dynamic response by the use of a complex cavity shape. A complex cavity shape combined with proper placement of the input transducers, the output transducers, the impedance discontinuities located in the cavity, etc., can result in a high number of propagation paths for the waves that travel in the cavity, with a wide range of reflections. Reflections (which yield mode conversions), wave dispersion, and the other phenomena discussed below result in a rich dynamic response.

The cavity geometry can be convex or non-convex. In many situations, convex geometries are the most suitable configuration. Non-convex geometries can be used if it is known (or desired for the application under consideration) that some subset of inputs have only a weak relationship with a subset of the outputs. In such a situation, it can be advantageous to place the transducers for these inputs in a portion of the cavity that is topologically weakly connected to the rest of the cavity.

### 5. Impedance Discontinuities in the Cavity

An AWRC device may achieve a rich dynamic response by the use of designed impedance discontinuities within the cavity (e.g. 95 and 96 on FIG. 9). Such discontinuities can be implemented by geometric and material features such as through holes (i.e. holes that extend through the thickness of the thin-film medium), partial holes (i.e. holes that do not extend through the thickness of the thin-film medium), local thickness increases, inclusions, deliberate defects, or any other local variation of material property that affects wave propagation.

Impedance discontinuities within the cavity induce reflections and mode conversions, and add to the reflections and mode conversions induced by the outer boundaries of the cavity. To enhance the richness of the dynamic response of the AWRC device, the internal impedance discontinuities are located randomly in the cavity. However, it has been shown (cf. Abel Klein and Andrew Koines in “A General Framework for Localization of Classical Waves: I. Inhomogeneous Media and Defect Eigenmodes”, Mathematical Physics, Analysis and Geometry, 2001, 4(2):97-130, and “A General Framework for Localization of Classical Waves: II. Random Media”, Mathematical Physics, Analysis and Geometry, 2004, 7(2): 151-185) that very disordered medium can cause the wave energy to become partially trapped in a part of the cavity, and not interact with the rest of the cavity. To avoid this condition, the nonuniformity should be designed with care.

### 6. Mode Conversion

An AWRC device may achieve a rich dynamic response by use of wave mode conversion in the cavity. Mode conversion is a property of elastic waves propagating in a medium. When the propagating (say, longitudinal) wave is incident on an internal or external boundary, the longitudinal wave is reflected. In addition, due to transverse motion at the boundary, SH waves are generated. These SH waves propagate to generate further longitudinal and/or SH waves at other boundaries. The degree of mode conversion is dependent on the boundary geometry (both internal and external), as well as the Poisson ratio of the materials in the media.

### 7. Wave Diffraction

The richness of the dynamic response of an AWRC device may be enhanced by the use of wave diffraction in the cavity. A wave undergoes diffraction when it encounters an obstacle (created by a localized impedance discontinuity) that bends the wave, or when the wave spreads after emerging from an opening (also created by an impedance discontinuity). The diffraction effects are more pronounced when the size of the obstacle or opening is comparable to the wavelength of the wave.

### 8. Wave Dispersion

The richness of the dynamic response of an AWRC device may be enhanced by the use of wave dispersion in the cavity. Elastic waves propagating in a medium exhibit dispersion when the velocity of wave propagation c depends on frequency ω, or/and on the material properties of the medium. Dispersion results in wave separating into their constituent frequencies as they propagate through the medium.

### 9. Non-Uniform Medium

The richness of the dynamic response of an AWRC device can be enhanced by the use of a non-uniform propagation medium. The cavity can be composed on several separate regions (larger than localized impedance discontinuities discussed above), each made of a separate medium, so the propagating waves undergo refraction they pass from one region into another.

### 10. Non-Linear Medium

The richness of the dynamic response of an AWRC device can be enhanced by the use of a non-linear propagation medium. Nonlinearity can be introduced when the cavity is made of a piezoelectric material, in which case the mechanical response and the electrostatic response of the propagating medium are coupled, and the stiffness matrix of the medium is nonlinear.

Furthermore, non-linearity can be created when the input signals are strong enough to push the cavity or/and transducer materials out of their elastic-response regime, or to saturate the strain distribution in the cavity.

### 11. Feedback

The richness of the dynamic response of an AWRC device can be enhanced by the use of feedback. The addition of explicit non-linear feedback into the reservoir causes it to cease to be an LTI system, but can enhance the richness of its dynamic response and thereby introduce new capabilities into its projection abilities.

Electrical feedback can be provided from one or more output transducers (e.g. 98B on FIG. 9) to one or more input transducers (e.g. 98A). The feedback transducers can be dedicated to the feedback function. Alternately, the transducers can be input or/and output transducers that are used during the regular operation of the AWRC device, and that are time-multiplexed to provide feedback. In the embodiment presented on FIG. 9, the feedback circuit 99 has electrical input and output ports, but one skilled in the art readily understands that feedback can be implemented directly by mechanical means or indirectly by other means.

The electrical feedback operation can have gain; it can be linear or non-linear; it can instantaneous or time-delayed, etc. Feedback can also be provided by mechanical connections or by other means.

In the context of machine learning, output-to-input feedback can be thought of as “teacher forcing” wherein the target is fed back into the input. This feature can be disabled during training or open loop operation. It is also possible to duty cycle these connections to mix teacher forcing and training.

### 12. Reservoir Property Tuning

The richness of the dynamic response of an AWRC device can be enhanced by the use of a tunable propagation medium. We refer to a tunable propagation medium as a medium that has a propagation-related property that can be altered (or changed or tuned) after manufacturing, in a repeatable manner. For an acoustic medium, the material properties that affect wave propagation include the coefficients of the stiffness matrix, modulus of elasticity, Poisson ratio, wave velocity, etc. Material properties can be altered by electrical or magnetic or optical or thermal means.

Certain material property tuning processes are extremely fast—of the order of nanoseconds—and can enable new capabilities in a AWRC device-based machine learning system.

Certain material properties can be altered in a continuous manner, others in a discrete manner. In both cases, tunability can be exploited as a switch. A reservoir that incorporates a tunable material can be switched from one state to another. Thus, it is possible to “store” two or more different projections indexed by the tuning control means.

If the material property change is continuous, the material properties can be perturbed or dithered, and the effect on the operation of the AWRC device (and, if that is the case, on the learning process itself) can be observed.

### B. The Transducers

In an AWRC device, input signals may be applied to piezoelectric transducers to create traveling waves, via the reverse piezoelectric effect, that couple into the reservoir cavity. Waves from the cavity are sensed and read out by piezoelectric transducers using the direct piezoelectric effect. In the following discussion, piezoelectric transducers are assumed, but other transducers can perform similar functions.

### 1. Example Structure of the Transducer

Piezoelectric transducers convert electrical voltage or current to strain energy at the inputs, and strain energy to electrical voltage or current at the outputs. Piezoelectric transduction typically uses a single mode to perform the transduction. Modes that are most often used are the TE-mode or the LE-mode. In the TE-mode, the displacement or strain is in the direction of the applied electrical field (for the reverse piezoelectric effect); or the generated voltage is in the direction of the applied strain (for the direct piezoelectric effect). In the LE-mode, also known as a lateral, or contour, or Lamb mode, the strain is perpendicular to the direction of the applied electric field (and vice versa for the direct piezoelectric effect). For the both modes, as a consequence of the Poisson ratio of the material, a strain in one direction results in a related strain in the orthogonal directions. TE-mode transducer embodiments can use this property to launch inputs and receive outputs from the cavity. Other modes, including without limitation, bulk- and surface- modes can be used for transduction.

The transducers can be designed to achieve a specific response, i.e. to generate and couple into the reservoir a wave of specific characteristics. Several transducer parameters can be designed: the transducer's location, its total area, its shape (e.g. a point, a line or area port to the cavity), its connection to the cavity, etc. In addition, transducers can be designed to be operated in groups. For example, multiple transducers (whether adjacent or not) can be coupled or activated together or with a certain time delay so that the acoustic wave is launched into the reservoir along a preferred axis or direction, or with a specific propagation lag or phase shift between the various transducers

### 2. Location of the Transducers

With a thin-film cavity manufactured with common thin-film MEMS processes, transducers can be readily placed on the lateral periphery of a cavity, as depicted in FIGS. 12 and 13. However, transducers may also be located in the interior of the cavity.

It can be advantageous to define transducers at many locations of the cavity, then select a random subset of transducers as input transducers and output transducers as a method to increase the variety of response dynamics of the reservoir.

Further, it can be advantageous to locate transducers across (on the top or the bottom of) the cavity, for example in cases where the AWRC device is to be used with 2D input data, such as images.

### 3. Functionality of the Transducers

In many of the embodiments presented herein, the piezoelectric transducers operate either as input transducers or as output transducers. In many applications, the input transducers are connected to driver amplifiers or other electrical or electronic circuits to filter, amplify, or otherwise shape the waves generated by these input transducers. Likewise, in many applications, output transducers are connected to low-noise amplifiers or other electrical or electronic circuits to amplify, filter, or otherwise shape the output signals.

Alternately, because of the duality of the forward and reverse piezoelectric effects, piezoelectric transducers can be operated sequentially as input transducers and output transducers. Sequential input/output operation is possible when the transducers (and the AWRC device) are designed to sense the output signals at different times than when the input signals are applied. In such a sequential mode of operation, for example, the output signals may be sensed after the input signals are applied; alternately, the output signal sensing operations may be time-interleaved with the application of the input signals. A sequential dual-functionality transducer may be connected to the appropriate data source (optionally through a driver amplifier) when it is operated as an input transducer, and it may be connected to the appropriate data sink (optionally through a low noise amplifier) when it is operated as an output amplifier. The connections are switched according to the then-current function of the transducer. Note that the dual functionality concept applies to other types of transducers such as inductive transducers, which can be used in electromagnetic-wave reservoir computing devices.

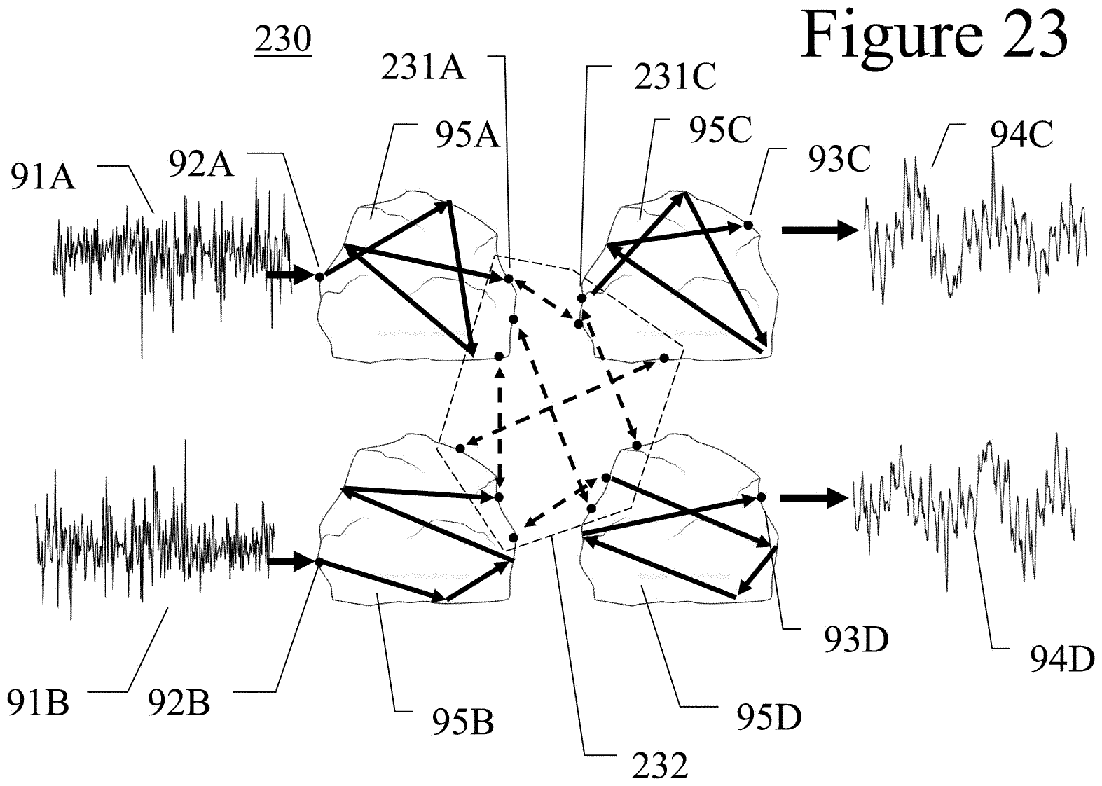

Alternately, in networked reservoir applications, certain piezoelectric transducers can be used as simultaneously bi-directional transducers to connect separate reservoirs to form a compound reservoir. As depicted in FIG. 23, in the compound reservoir formed by reservoirs 95A-95D, transducer 231A of reservoir 95A generates an output voltage when impinged by waves that travel through reservoir 95A; simultaneously, transducer 231A receives input voltages from other simultaneously bi-directional transducers (such as transducer 231C of reservoir 95C) and generates waves into reservoir 95A as a result. The separate reservoirs can be connected in any desired manner (e.g. strongly (i.e. more direct); loosely (i.e. less direct); locally, etc.) via the interconnect architecture.

### 4. Test/Characterization Transducers

Transducers in AWRC devices are typically used to apply input signals to the reservoir and read out output signals from the reservoir, to perform random projection computations.

However, transducers can be used for test and characterization purposes. Transducers can be used to measure or monitor the properties of the reservoir, such as wave velocity, transducer gain, loss in the cavity, etc. A simple time-of-flight measurement between two test transducers can be used to characterize the wave velocity of the cavity.

Transducers can be dedicated to performing test and characterization. Alternately, input or/and output transducers that are used during the regular operation of the AWRC device can be re-purposed temporarily to perform test and characterization.

### 5. Use of Transducers for Reservoir Tuning

As waves propagate in the cavity, some waves reach and impinge the input and output transducers. If a transducer presents an acoustic impedance to impinging waves that is equal to the acoustic impedance of the cavity, then all impinging acoustic wave energy is converted to electrical energy by the transducer. Alternately, if a transducer presents an acoustic impedance that is not equal to the acoustic impedance of the cavity, then part of the impinging wave will reflect off the transducer.

The acoustic impedance presented by an output transducer to the waves propagating in the cavity is set by the response of the transducer itself and by the impedance presented by the electronic sense/amplification circuit connected to the output transducer. Likewise, the acoustic impedance presented by an input transducer to waves propagating in the cavity is set by the response of the transducer itself and by the impedance presented by the electronic drive circuit connected to the input transducer. Therefore, it is possible to vary the acoustic impedance presented by transducers, and thereby the response of the reservoir.

### 6. Using Reservoir Tuning for Machine Learning

It is possible to use the transducer-impedance-based reservoir tuning scheme described above to enable certain unsupervised learning tasks. When the impedance of a wave impinging a transducer does not match the impedance of the transducer, a portion of the wave is converted to electrical energy by the transducer, and a portion of the wave is reflected back into the cavity. This reflected wave can be thought of as back propagation of the error signal.

Since the transducer impedance is tunable, it is possible to tune the impedance of the transducers to achieve certain goals, much like selecting weights in a neural network. Specifically, the transducer impedance values can be adjusted until the impinging wave no longer reflects into the cavity, and all of the wave energy is converted out of the cavity.

The tuning process can be automated further. Since the acoustic impedance of a transducer is determined in part by the impedance of the circuit that is connected to the transducer, then these transducer circuit impedances can act as training targets. The tuning process of the AWRC device consists in adjusting the feedback gains to match the transducer circuit impedances.

### C. The Packaging

In the AWRC device depicted in FIGS. 12 and 13, the cavity is formed by a MEMS thin-film structure. A mechanically-compliant suspension is used to support the entire reservoir and isolate it from the environment. The suspension is carefully designed so that the reservoir dynamics are isolated from the environment, while simultaneously ensuring that the reservoir structure is anchored to the substrate. Suspensions can be mechanical beams or springs substantially in the plane of the reservoir; or pillar structures that connect to the reservoir vertically from the substrate or the package. However, the suspension structure should not impede the propagation of elastic waves within the cavity, or the generation/reading of elastic waves at the transducers.

The reservoir and its suspension are built on a substrate. The substrate can contain electrical circuits. The reservoir and suspension may be isolated from the environment. This can be done using a device-level cap, or a wafer level cap can be made over the reservoir structure via wafer-to-wafer bonding. The reservoir need not be hermetically isolated from the environment; a cap that substantially protects it from external impurities and moisture is sufficient for most applications. If the substrate does not include circuits, the reservoir die can be co-packaged with a circuit die.

### IV. Networks of Reservoirs

The size of MEMS-based reservoirs is limited by manufacturing and other constraints. One method to create a large reservoir is to connect several reservoirs, as depicted on FIG. 23. As discussed previously, LTI systems can be composed to realize new LTI systems. As a result, a compound linear reservoir can be composed straightforwardly by interconnecting two or more linear reservoir to their nearest neighbors. As long as the reservoir-to-reservoir interconnect is linear (including, potentially, a gain stage), the resulting network is also a reservoir. Other composition strategies—analogous to network topologies—can also be considered. Introduction of nonlinearity—via circuits, or nonlinear materials, or non-linear feedback, will result in a non-linear compound reservoir.

A network of reservoirs can be used in several ways. The network can accommodate many more ports than a single reservoir. The network can be designed to have a longer-duration memory or a more complex response than a single reservoir. The network can be configured to perform incremental learning. For example, if the network is learning a relationship between an input and an ultimate output that is long sequence of convolutional operations, the relationship can be learned in discrete stages using discrete reservoirs to learn each stage. According to such operation, a first reservoir will learn a first relationship between the original input and a first intermediate output, a second reservoir will learn a relationship between the first intermediate output (the first intermediate input of the second stage) and the second stage learns the relationship between the first intermediate input and an output that can be the ultimate output in a two stage example or a second intermediate output if the learning requires more than two stages. Compound reservoirs can be suited for applications such as sequence-to-sequence learning, autoencoders, denoising autoencoders, stacked autoencoders, adversarial reservoirs, without limitation.

Further, it is possible to implement committee-based learning with groups of AWRC devices. Ensembles or groups of AWRC can be trained on the same task, with different sets of random ports. At the outputs, a voting scheme would select the best set of parameters after training.

### V. Some Distinctions over Other Devices

An AWRC device differs from other devices, both operationally and structurally, in many different ways.

### A. Differences of Operation

For example, an AWRC device may differ significantly from existing implementations of random projection and neural network computational circuits.

First, AWRC devices have a physical reservoir, and therefore feature a local connectivity inside the reservoir. By contrast, traditional reservoir computing concepts (Echo State Networks and Liquid State Machines) have a digital reservoir, and therefore feature global node-to-node connectivity inside the reservoir. In addition, physical reservoirs are intrinsically lossy, whereas digital reservoirs can have gain greater than 1 between nodes, and nodes can form closed loops that have a divergent or oscillatory response. Therefore, AWRC devices are more likely to be numerically stable.

Second, AWRC devices perform computations passively by letting acoustic waves propagate in a cavity. As a result, the high-dimensional projection of input data is performed without power consumption. By contrast, circuit implementations of reservoir computing devices perform thousands of computations (additions and multiplications on binary data) explicitly at every time step of operation of the reservoir, and each computation dissipates some electrical power.

Third, AWRC devices use acoustic waves that propagate in solid-state elastic materials to compute and transport data from inputs to outputs. Such materials have an acoustic wave velocity that ranges from 1,000 meter per second to 15,000 meter per second. By contrast, in reservoir computing devices that use optical waves or electromagnetic waves, the wave velocity ranges from 75,000,000 meters per second (in a material such as germanium) to 300,000,000 meters per second (in vacuum), which is 5,000 to 300,000 times faster than the acoustic wave velocities cited above. As a result, reservoir computing devices that use optical waves or electromagnetic waves would be much larger that AWRC devices for applications that have equal input data rates.

Therefore, it is clear that AWRC devices may differ operationally from other devices in several ways.

### B. Differences of Structure

As another example, AWRC devices are unique in their use of wave propagation in a reservoir to perform random projection computations. Known devices that most resemble AWRC devices in terms of structure are bulk acoustic wave (BAW) resonators and surface acoustic wave (SAW) filters. But even BAW resonators and SAW filters differ greatly from AWRC devices.

First, compare AWRC devices to BAW resonators. In terms of acoustic operation, BAW resonators function by confining a standing wave, in a cavity that supports a single mode of resonance with very high quality factor. By contrast, AWRC devices function with traveling waves, in a cavity that supports tens to hundreds modes, each with a moderate quality factor. In terms of construction, BAW resonators are manufactured to minimize the non-uniformity of the acoustic propagation medium, so as to minimize wave reflections, mode conversion and loss. By contrast, AWRC devices may be manufactured with deliberate non-uniformities in the acoustic propagation medium, so as to induce wave reflections and mode conversion. In terms of overall response, BAW resonators are designed and manufactured to have a very linear response. By contrast, AWRC devices are typically designed and manufactured to have a non-linear response.

Second, compare AWRC devices to SAW filters. In terms of frequency response, SAW filters have a frequency response in a relatively narrow range of frequencies. By contrast, AWRC devices have a multi-resonant frequency response over at least one decade in frequency. In terms of construction, SAW filters are manufactured to minimize the non-uniformity of the acoustic propagation medium, so as to minimize wave reflections, mode conversion and loss. By contrast, AWRC devices may be manufactured with deliberate non-uniformities in the acoustic propagation medium, so as to induce wave reflections and mode conversion. In terms of overall response, SAW filters are designed and manufactured to have a very linear response. By contrast, AWRC devices are typically designed and manufactured to have a non-linear response.

Therefore, it is clear that AWRC devices differ structurally from the other devices in several ways.

### VI. Detailed Description of the Drawings

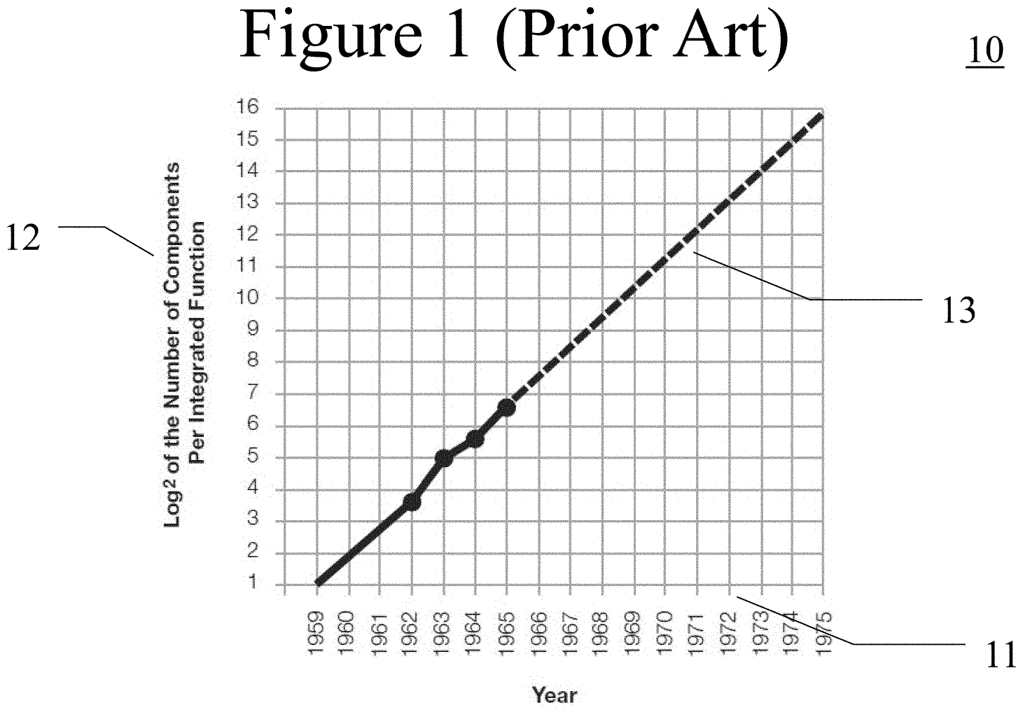

FIG. 1 is a plot 10 of Moore's Law that shows the growth in the number of transistors per function over time, taken from Gordon Moore's original paper (Gordon Moore, “Cramming more Components onto Integrated Circuits”, Electronics, 38(8), Apr. 19, 1965). The x-axis 11 is time in years. The y-axis 12 is the log of the number of components (on-chip transistors) per function. The curve 13 is the projected progression of the empirical Law from 1965 (when the paper was written) to 1975.

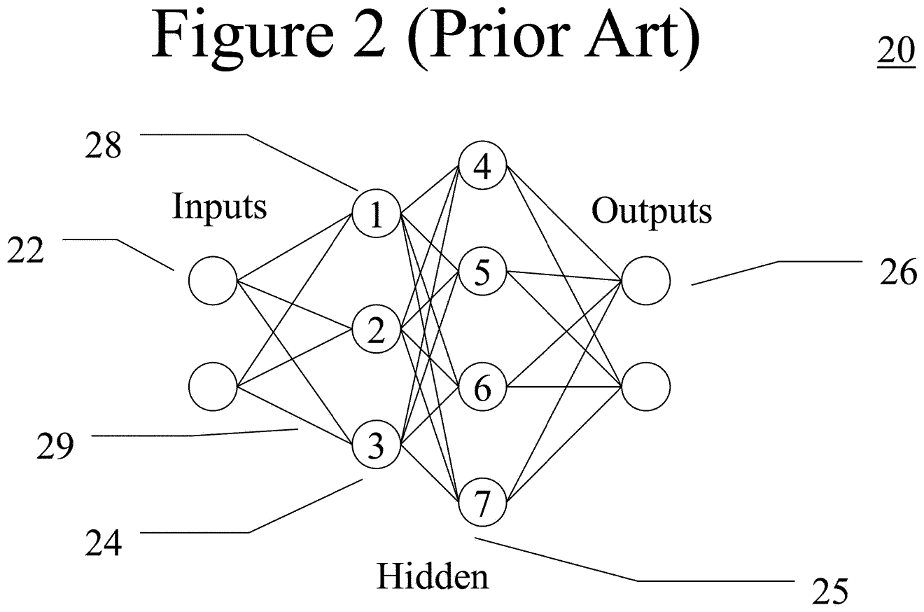

FIG. 2 is a diagram that depicts a simple feed-forward neural network 20 from the prior art. Several nonlinear neurons 28 are organized in two hidden layers and connected in a graph. The inputs 22 are connected via connections 29 to the neurons 1-3 that form first hidden layers 24. Neurons from the first hidden layer 24 are then connected to neurons 4-7 that form the second hidden layer 25. Neurons from the second hidden layer 25 are connected to outputs 26. All connections 29 between neurons go forward from layer-to-layer. Every incoming or outgoing connection 29 has a weight associated with it. The set of incoming connections into a neuron also optionally has a bias associated with it. A particular neuron fires or sends the signal to a downstream neuron of the weighted input (plus bias) exceeds a predetermined threshold.

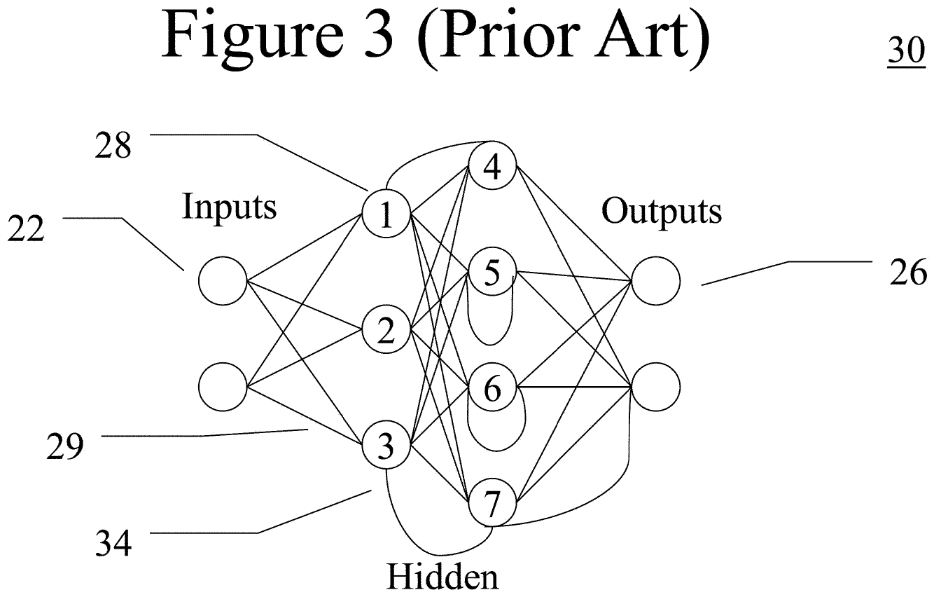

FIG. 3 is a diagram that depicts a simple recurrent neural network 30 from the prior art. Several nonlinear neurons 28 are organized in layers and connected in a graph. In this network, certain connections 29 between neurons between hidden layers or within a hidden layer are recurrent, i.e. they connect backward to a previous neuron (cf. neuron 7 to 3), or back to the same neuron (cf. neuron 6). Every incoming or outgoing connection 29 has a weight associated with it. The set of incoming connections 29 into a neuron also optionally has a bias associated with it. A particular neuron fires or sends the signal to a downstream neuron if the weighted input plus bias exceed a predetermined threshold.

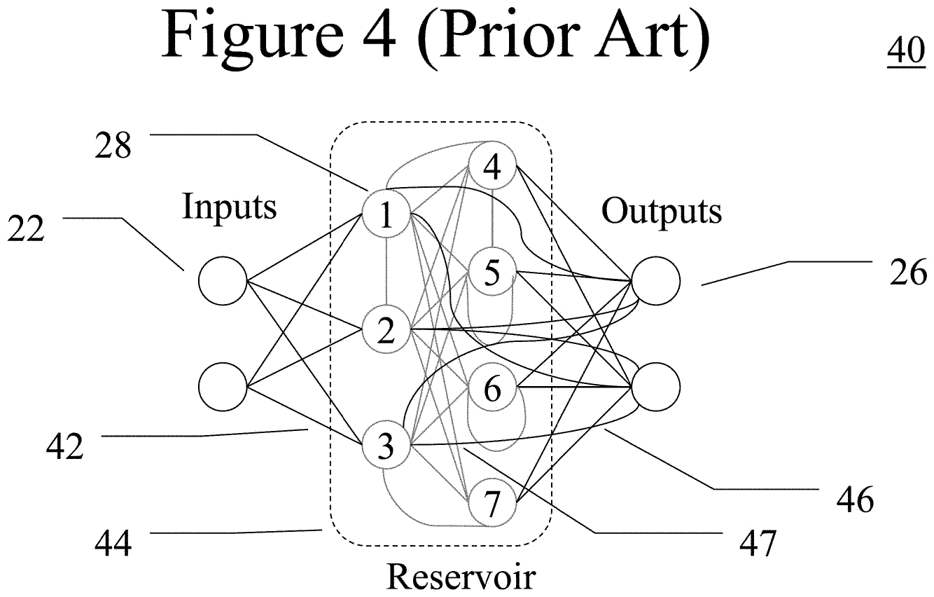

FIG. 4 is a diagram that depicts a simple reservoir neural network 40 from the prior art. Several nonlinear neurons 28 are organized in layers and connected in a graph. The inputs 22 are connected via connections 42 to reservoir 44 (composed of neurons 1 through 7). The reservoir neurons are fully connected to the outputs 26 via connections 46. Connections 47 between neurons in the reservoir 44 are random, i.e. the neuron pairs are selected randomly. Certain connections 47 within the reservoir are recurrent. The associated weights are chosen randomly and are not changed during training. Every incoming connection 42 or outgoing connection 46 has a trainable weight associated with it. The set of incoming connections into a neuron also optionally has a trainable bias associated with it. A particular neuron fires or sends the signal to a downstream neuron if the weighted input plus bias exceed a predetermined threshold.

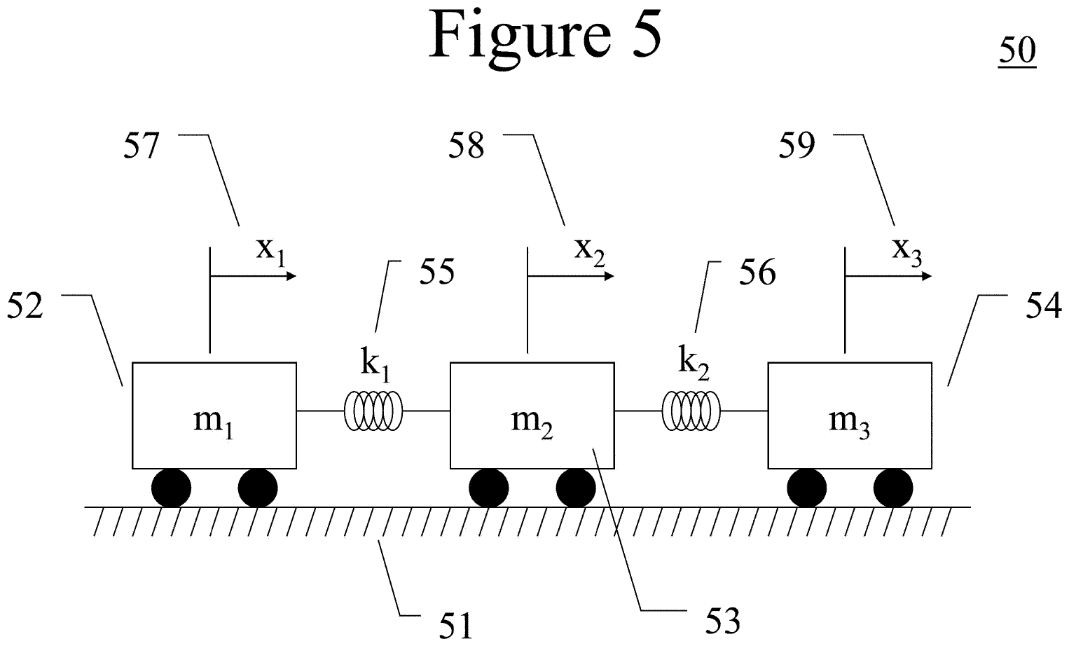

FIG. 5 is diagram that depicts a single degree-of-freedom mechanical system 50. Three masses 52, 53 and 54 with masses m₁, m₂ and m₃, respectively, are placed on a support 51, and can translate in the x-axis. They are connected by springs 55 and 56 with spring constants k₁ and k₂, respectively. The displacements 57, 58 and 59 with values x₁, x₂ and x₃ respectively, are all along the x-axis.

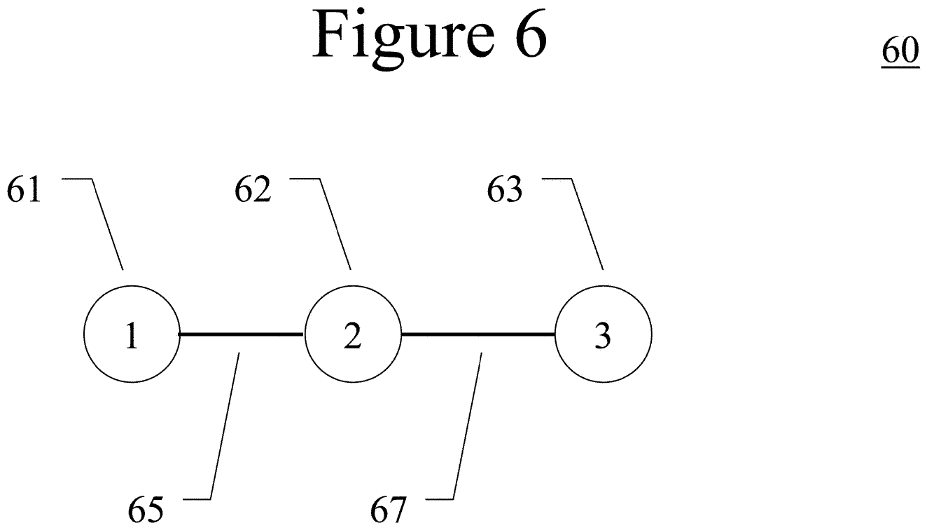

FIG. 6 is graph representation 60 of the mechanical system 50 from FIG. 5. Node 61 corresponds to mass 52, node 62 corresponds to mass 53, and node 63 corresponds to mass 54. Edge 65 corresponds to spring 55 and edge 66 corresponds to spring 66.

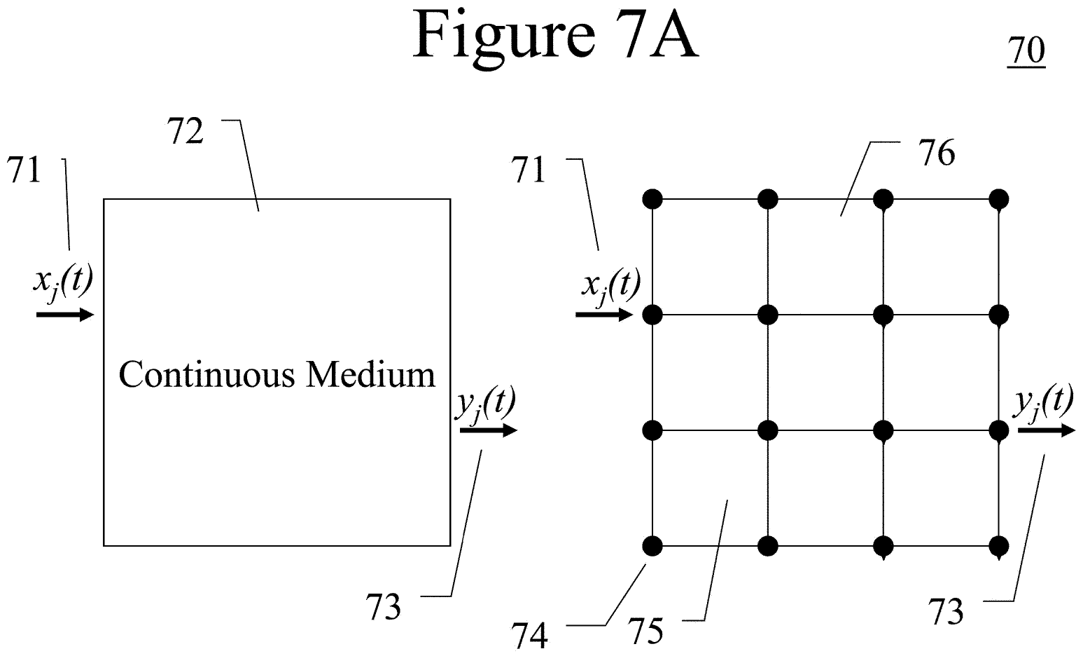

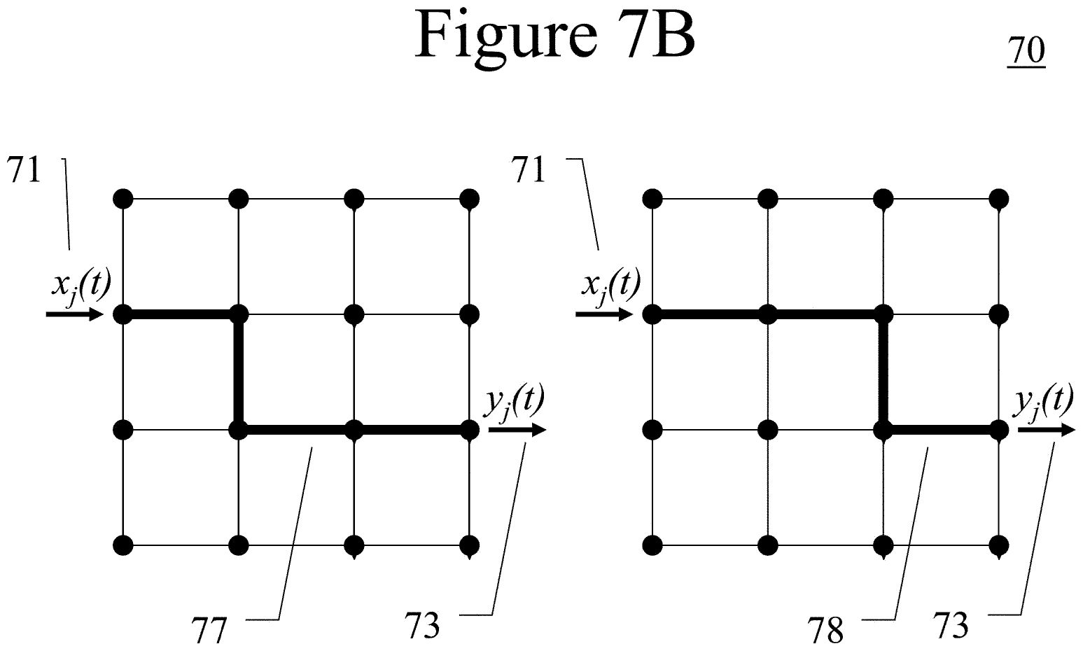

FIG. 7A is a diagram 70 that depicts a continuous medium 72 and its finite element representation 76. The medium 72 is subject to a stimulus input 71, that generates an output 73. In the finite element representation, the medium is discretized into elements 75 and nodes 74. Adjacent elements interact through their mutual nodes. The input 71 passes from element to element, via mechanical or other interactions at the nodes, until it emerges as output 73.

FIG. 7B is a diagram that depicts the finite element representation from FIG. 7A, showing two possible energy-transfer paths 77 and 78 from input 71 to output 73. Ideal paths are shown. In a linear system with no internal gain (i.e. no internal energy source), the sum of energies along all possible paths from input 71 to output 73 equals the energy inserted into the system.

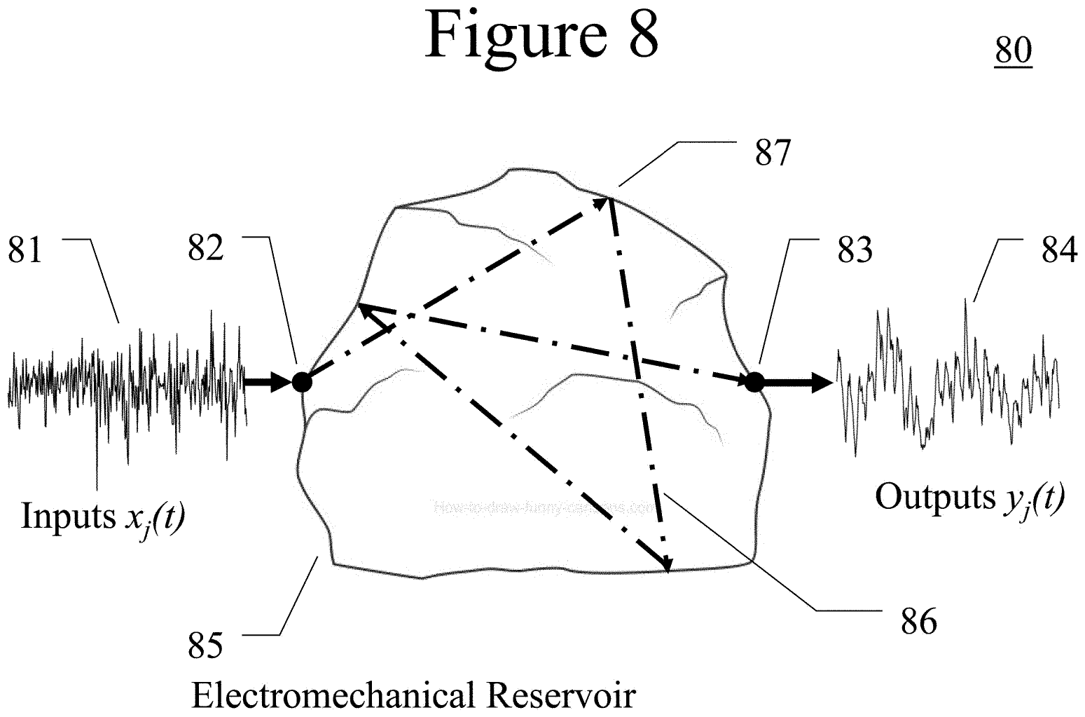

FIG. 8 is a diagram 80 that depicts an electromechanical reservoir 85. The geometry of the reservoir 85 is deliberately chosen to be non-symmetric so as to obtain rich dynamics. Input signal 81 is inserted at input transducer 82—in this case, the input signal is converted by the transducer as a force or an enforced displacement. The wavefront of the resulting elastic wave spreads out from transducer 82 into the reservoir 85's cavity. One possible path 86 is shown along with boundary reflections 87. At the boundary reflections 87, mode conversion occurs as a consequence of the Poisson ratio. This results in additional waves being launched. The output displacement, velocity, acceleration or force 84 is converted by output transducer 83.

FIG. 9 is a diagram 90 that depicts an electromechanical reservoir 85, with features that enable random projection computation. The reservoir cavity is surrounded by transducers 91. Two inclusions that create impedance discontinuities within reservoir 85 are shown. Inclusion 95 has cylindrical geometry, and is a hole through the cavity. Inclusion 96 has rectangular geometry, and is filled with a material different from the cavity material. Input signal 81 is applied at input transducer 82 via amplifier 88. The wavefront 92 of the resulting elastic wave propagates out from transducer 82 into the cavity. Two possible paths 93 and 94 are shown on FIG. 9. Path 93 propagates through the cavity, undergoes reflection at the exterior boundaries, then reaches output transducer 83. Path 94 propagates through the cavity, and is first reflected internally at inclusion 95; then it is reflected at an exterior boundary; then it is reflected at inclusion 96, where mode conversion occurs, generating new secondary propagating wavefronts 97. Finally, path 94 reaches output transducer 83. The output signal 84 of the reservoir 85 is read at output transducer 83 via amplifier 89. Additionally, the wavefront is sensed at output transducer 98A. The feedback signal is passed through electrical circuit 99, before being applied at input transducer 98B.

FIGS. 10A to 10H are diagrams that depict the operation of an acoustic wave reservoir computing device. FIG. 10A depicts a reservoir 103 with idealized pentagon geometry, no internal impedance discontinuities, two input transducers 105A and 105B and two output transducers 107A and 107B. FIG. 10B depicts input signal 101A being applied to input transducer 105A, and the resulting wave 106A that propagates through reservoir 103. For the sake of simplicity, input signal 101A is depicted as being a single bipolar pulse. Initially, wave 106A propagates radially from input transducer 105A. Then, parts of wave 106A reflect on parts of the boundary of reservoir 103, and wave 106A splits and propagates along various directions. FIG. 10C depicts three propagation paths 108AA1, 108AA2 and 108AA3 taken by wave 106A from input transducer 105A to output transducer 107A. The waves that propagate along these three paths reach output transducer 107A with different delays, and with different levels of attenuation and distortion (caused by reflections, mode conversions, etc.). The sum of all waves generated by input transducer 105A that reach output transducer 107A yield output signal 102AA. On FIG. 10C and the other figures in this series, the illustrations of the output signals are truncated in time and their shape is conceptual, for clarity. FIG. 10D depicts three propagation paths 108AB1, 108AB2 and 108AB3 taken by wave 106A from input transducer 105A to output transducer 107B. The waves that propagate along these three paths reach output transducer 107B with different delays, and with different levels of attenuation and distortion (caused by reflections, mode conversions, etc.). The sum of all waves generated by input transducer 105A that reach output transducer 107B yield output signal 102BA.

FIG. 10E depicts input signal 101B being applied to input transducer 105B, and the resulting wave 106B that propagates through reservoir 103. Initially, wave 106B propagates radially from input transducer 105B. Then, parts of wave 106B reflect on parts of the boundary of reservoir 103, and wave 106B splits and propagates along various directions. FIG. 10F depicts three propagation paths 108BA1, 108BA2 and 108BA3 taken by wave 106B from input transducer 105B to output transducer 107A. The waves that propagate along these three paths reach output transducer 107A with different delays, and with different levels of attenuation and distortion (caused by reflections, mode conversions, etc.). The sum of all waves generated by input transducer 105B that reach output transducer 107A yield output signal 102AB. FIG. 10G depicts three propagation paths 108BB1, 108BB2 and 108BB3 taken by wave 106B from input transducer 105B to output transducer 107B. The waves that propagate along these three paths reach output transducer 107B with different delays, and with different levels of attenuation and distortion (caused by reflections, mode conversions, etc.). The sum of all waves generated by input transducer 105B that reach output transducer 107B yield output signal 102BB.

FIG. 10H depicts the complete output signals 102A and 102B output by output transducers 107A and 107B respectively. Output signal 102A is the sum of output signals 102AA and 102AB depicts on previous figures. Likewise, output signal 102B is the sum of output signals 102BA and 102BB depicts on previous figures. In the above, we have assumed that the input and output transducers are linear, but one skilled in the art readily appreciates that no physical transducer is perfectly linear, and besides that it can be desirable to use transducers with a non-linear response to enhance the richness of the dynamic response of the AWRC device.

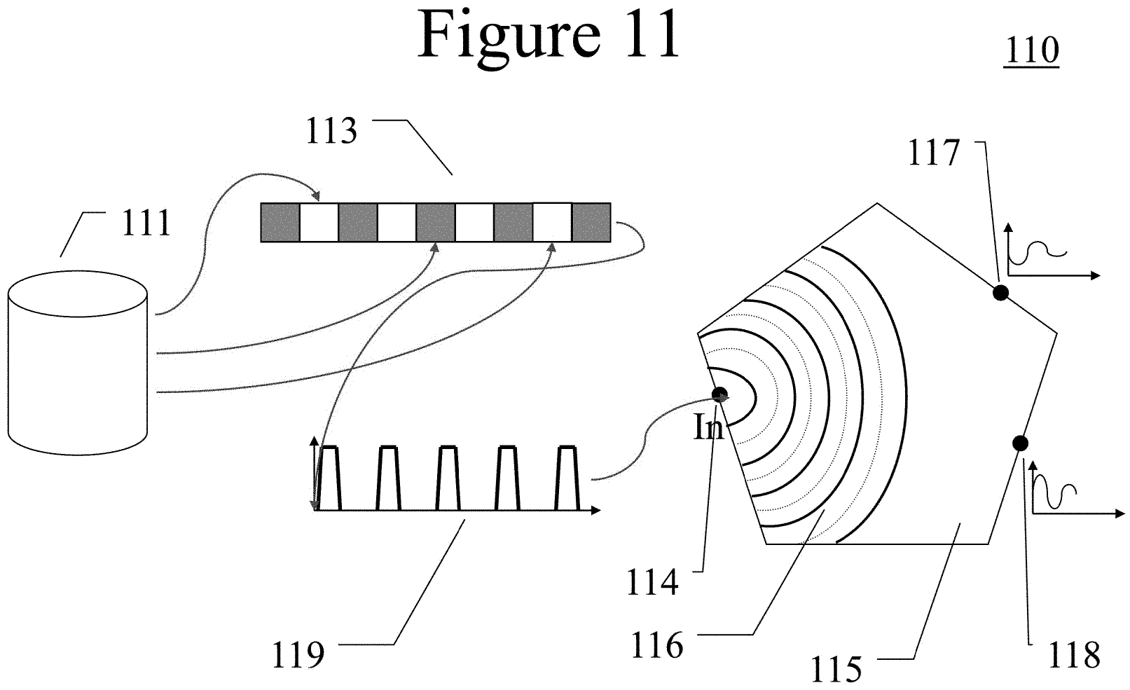

FIG. 11 is a diagram 110 that depicts a method by which input data 111 can be fed into reservoir 115. The reservoir 115 is shown to be a pentagon, but other asymmetrical shapes are applicable. Input data 111 is first processed to form time sequence 113, which can be multi-dimensional. Then, time sequence 113 is encoded into input signal 119; typically, input signal 119 is a voltage signal, but it can as well be a current signal, or a charge signal, or an electric field signal, or a magnetic field signal, etc. Input signal 119 is applied to input transducer 114, which induces a force, or a displacement, or a strain, etc. to the reservoir 115. The positions of the input transducers are chosen randomly on the periphery, top or bottom of the reservoir. The wavefronts 116 propagate through the reservoir cavity. Reflections at external and internal (not shown) boundaries cause mode conversion, and increase the richness of the dynamics. After a period of time that is greater than the row input time, and not more than the dissipation time of the reservoir, the outputs are read at output transducers 117 and 118.

FIG. 12 is a diagram that depicts a finite-element solid model 120 of a preferred embodiment of a reservoir where the cavity is surrounded by piezoelectric TE-mode transducers. The model is drawn to scale in the plane, but layer thicknesses are exaggerated for clarity. The cavity 121 has an asymmetric geometry as well as internal boundaries 122, in the form of through-holes. The cavity is surrounded by piezoelectric TE-mode transducer material layer 124. Passive or active temperature compensation of the transducer response is optionally included. A top conductive electrode 123 defines the electro-mechanically active region of a transducer. A lower conductive electrode 128 is present under at least the transducer material layer 124. Electrode 128 may also be present under the cavity 121. In this embodiment, transducer 126 is assigned to be an input transducer, and transducers 127 are assigned to be output transducers. The other transducers may optionally be used for feedback, self-test or remain unused.

FIG. 13 is a diagram that depicts a finite-element solid model 130 of an alternate embodiment of a reservoir where the cavity is surrounded by piezoelectric LE- or contour-mode transducers. The model is drawn to scale in the plane, but layer thicknesses are exaggerated for clarity. The cavity 131 has an asymmetric geometry as well as internal boundaries 132, in the form of through-holes. The cavity is surrounded by piezoelectric LE- or contour-mode transducer material layer 134. Passive or active temperature compensation of the transducer response is optionally included. A set of top conductive electrode-pairs 133 defines the electro-mechanically active region of a transducer. A lower conductive electrode 138 is optionally present under the transducer material layer 134 and/or the cavity 131. A transducer 135 consists of a set of electrode-pairs. The transducers are used for input or output, and may optionally be used for feedback, self-test or remain unused. The suspension structure is not shown.

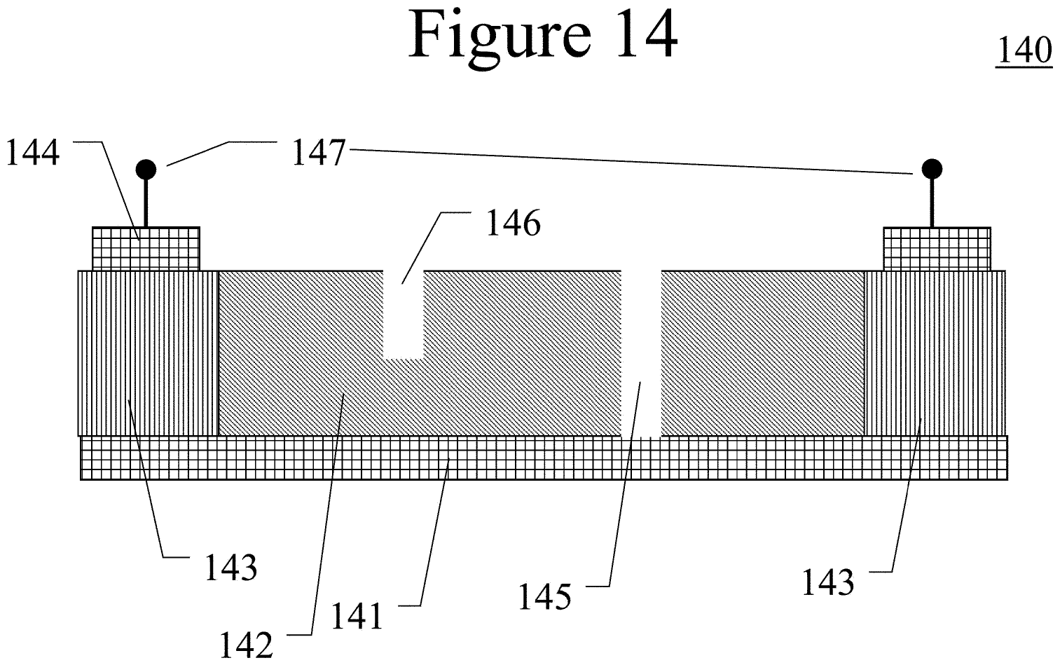

FIG. 14 is a diagram that depicts a cross-section 140 of the embodiments 120 and 130 presented on FIGS. 12 and 13. The lower conductive electrode 128 of embodiment 120 and the lower conductive electrode 138 of embodiment 130 are designated here as conductive layer 141. The cavity material 121 of embodiment 120 and the cavity material 131 of embodiment 130 are designated here as layer 142. Layer 142 can be a linear, non-linear, piezoelectric, electrostrictive or photoelastic material or stack of materials. This layer contains patterned holes or inclusions 122 or 132 that may go through the thickness of the layer 145, or be partial 146. The transducer material layer 124 of embodiment 120 and the transducer material layer 134 of embodiment 130 are designated here as piezoelectric transducer material layer 143 that is placed at the periphery of the cavity layer 142. The top electrode—which define the electro-mechanically active region of each transducers, both for the TE-mode transducers of embodiment 120 and the LE-mode transducers of embodiment 130—is designated here as conductive layer 144. All input, output, feedback, self-test, or unused transducers are connected through an electrical port 147 made of conductive layer 144. The suspension structure layers are not shown. Optional passive temperature compensation layers are not shown.

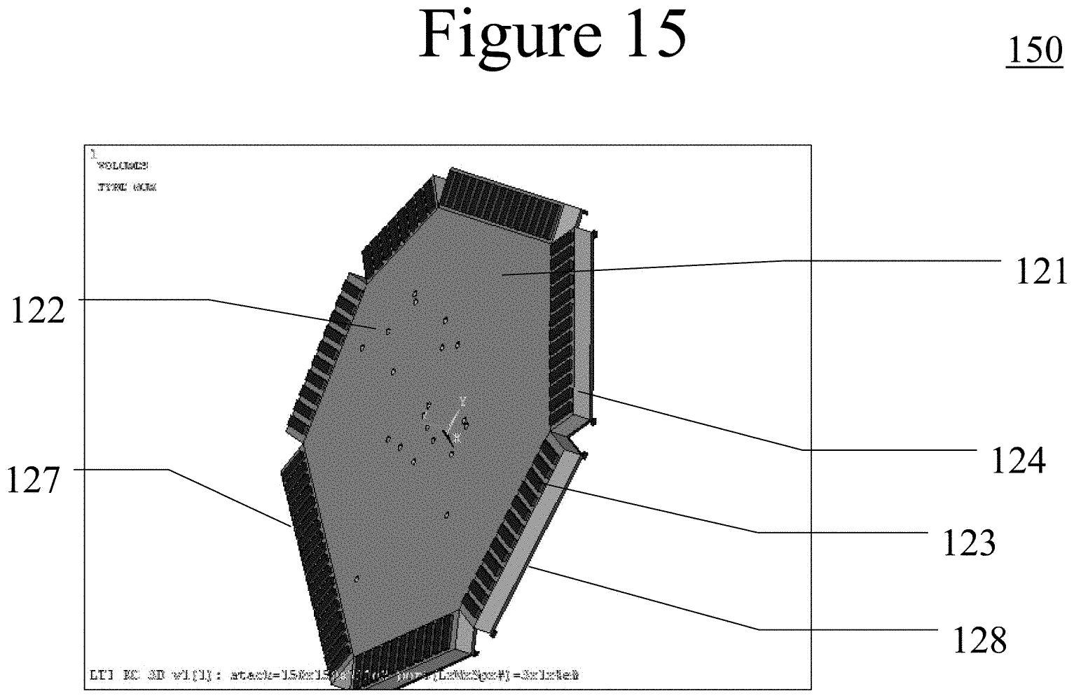

FIG. 15 is a diagram that depicts a finite-element solid model 150 of an alternate embodiment of a reservoir that is similar to embodiment 120 of FIG. 12, seen at an angle from the top. The model is drawn to scale in the plane, but layer thicknesses are exaggerated for clarity. The cavity 121 has an asymmetric geometry as well as internal boundaries 122, in the form of through-holes. The cavity is surrounded by piezoelectric TE-mode transducer material layer 124, though LE-mode or SAW transducers can also be manufactured. Passive or active temperature compensation of the transducer response is optionally included. A top conductive electrode 123 defines the electro-mechanically active region of each transducer. A lower conductive electrode 128 is present under at least the transducer material layer 124. Electrode 128 may also be present under the cavity 121. Transducers 127 are used for input and output and may optionally be used for feedback, self-test or remain unused.

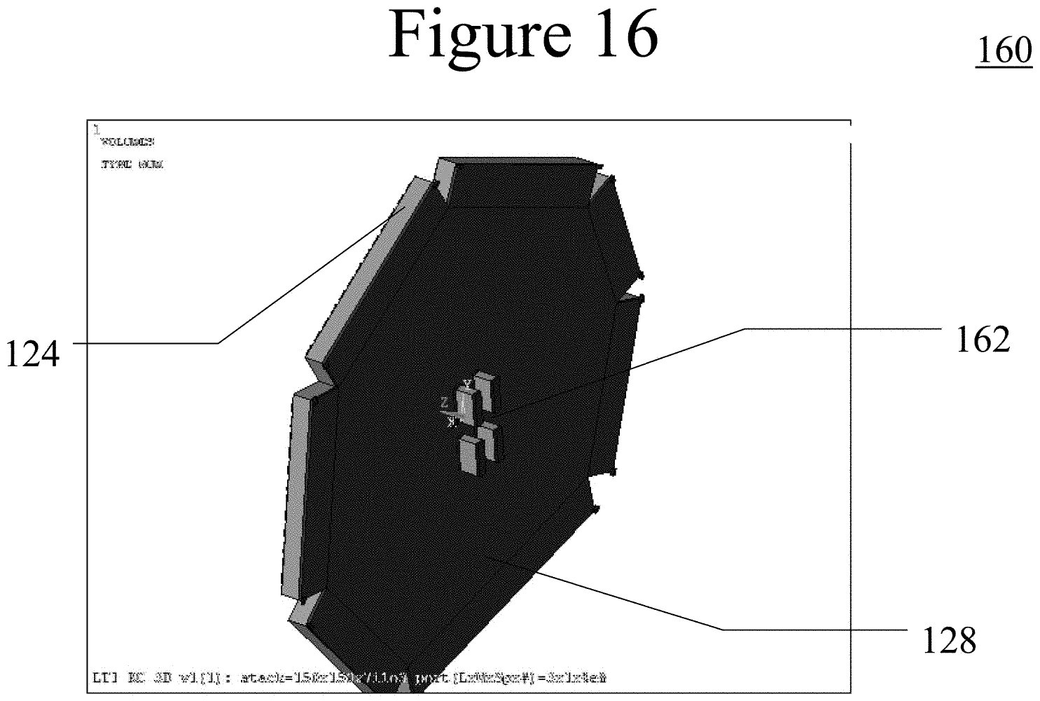

FIG. 16 is a diagram 160 that depicts the finite-element solid model presented on FIG. 15, seen at an angle from the bottom. In this view, the lower conductive electrode 128 is shown continuous under the transducer material layer 124. Additionally, one or more transducer elements 162 are placed on the bottom side of the reservoir. Similar elements can also be placed on top of the reservoir. These transducers can be used for additional input, output, feedback, self-test or tuning purposes.

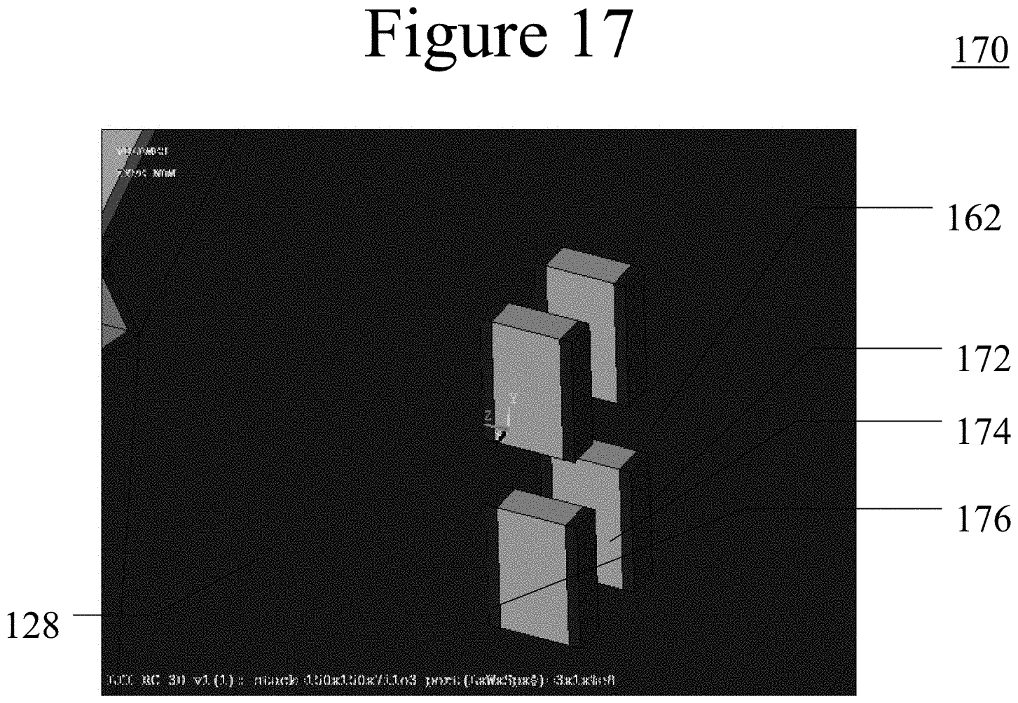

FIG. 17 is a diagram 170 that depicts the finite-element solid model presented on FIG. 16, seen at an angle from the bottom and zoomed in on transducer elements 162 that are placed on the bottom side of the reservoir. In this view, the lower conductive electrode 128 is shown. Four transducers 162 are present under electrode 128. Each of these transducers is configured as a TE-mode transducer, though LE-mode or SAW transducers can also be manufactured. Each transducer has a lower conductive electrode 172, a piezoelectric material layer 174, and a top conductive electrode 176. Passive or active temperature compensation of the transducer response is optionally included, but not shown. An optional acoustic coupler layer or layers between electrode 176 and electrode 128 is not shown. These transducers can be used for additional input, output, feedback, self-test or tuning purposes.

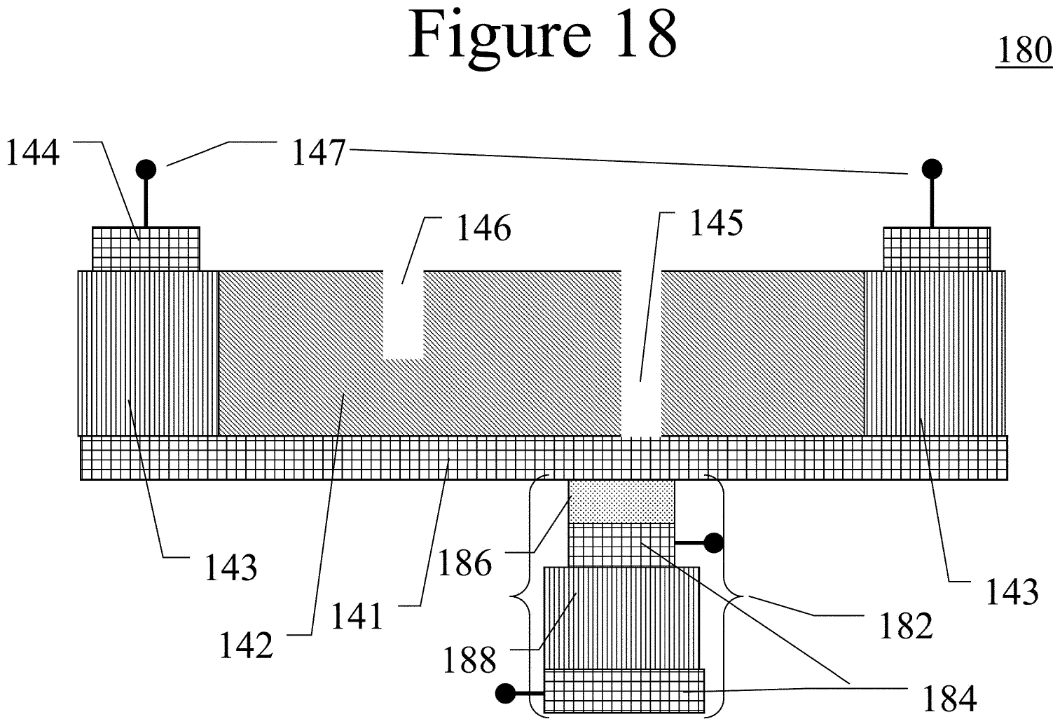

FIG. 18 is a diagram that depicts a cross-section 180 of embodiment 150 presented on FIG. 15, and is substantially similar to cross-section 140. The lower conductive electrode 128 of the embodiment 150 is the conductive layer 141. The cavity material 121 of embodiment 150 is layer 142. Layer 142 can be a linear, non-linear, piezoelectric, electrostrictive or photoelastic material or stack of materials. This layer contains patterned holes or inclusions 122 that may go through the thickness of the layer 145, or be partial 146. The transducer material layer 124 of embodiment 150 is the piezoelectric layer 143 that is placed at the periphery of the cavity layer 142. The top electrode is shown as conductive layer 144. All the input, output, feedback, self-test, or unused transducers are connected through an electrical port 147 made of a conductive layer 144. Additionally, one or more piezoelectric transducers 182 are placed below or above the cavity. They consist of conductive electrodes 184 placed above and below the transducer material layer 188. The transducer material layer 188 can additionally have electrostrictive or photoelastic properties. Acoustic coupler 186 can optionally be used to decouple the electrical response of the transducer material layer 188 from its mechanical influence on the cavity. The acoustic coupler 186 can consist of one or more material layers. The suspension structure layers are not shown. Optional passive temperature compensation layers are not shown.

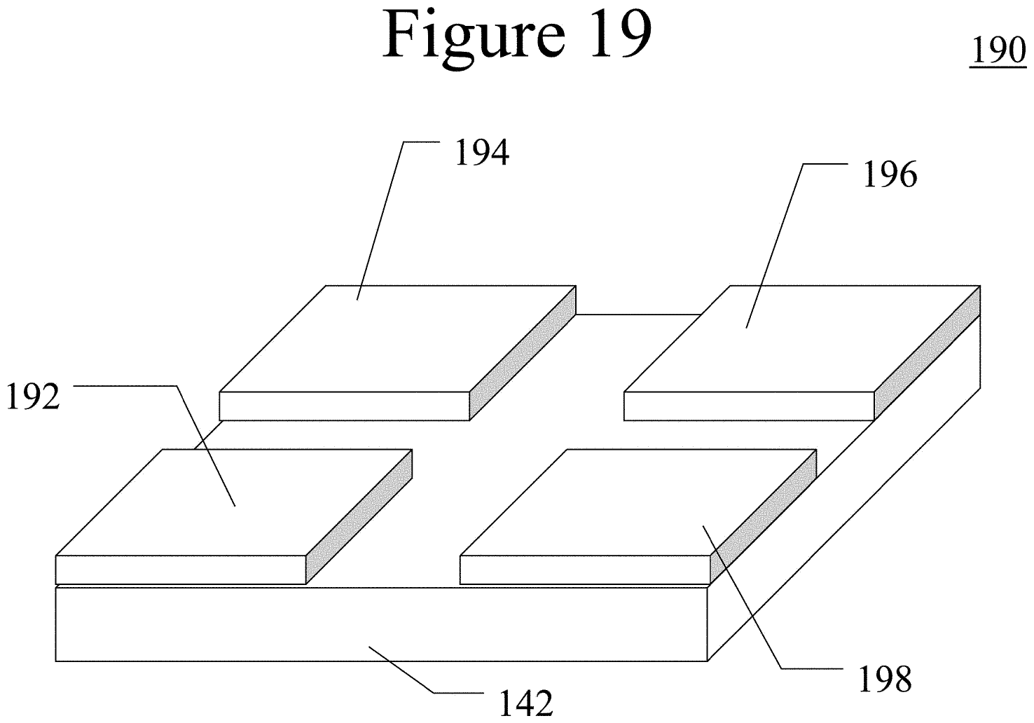

FIG. 19 is a diagram 190 that depicts of an alternate embodiment of the reservoir, in which TE-mode transducers are located above or below the cavity. In this embodiment, four TE-mode transducers 192, 94, 196 and 198 are located above the cavity 142, rather than at its periphery as shown on previous figures. These transducers can be used for input or output or may optionally be used for feedback, tuning, self-test or remain unused. Electrodes, optional acoustic coupling layers, and optional passive temperature compensation layers are not shown. The suspension structure layers are not shown.

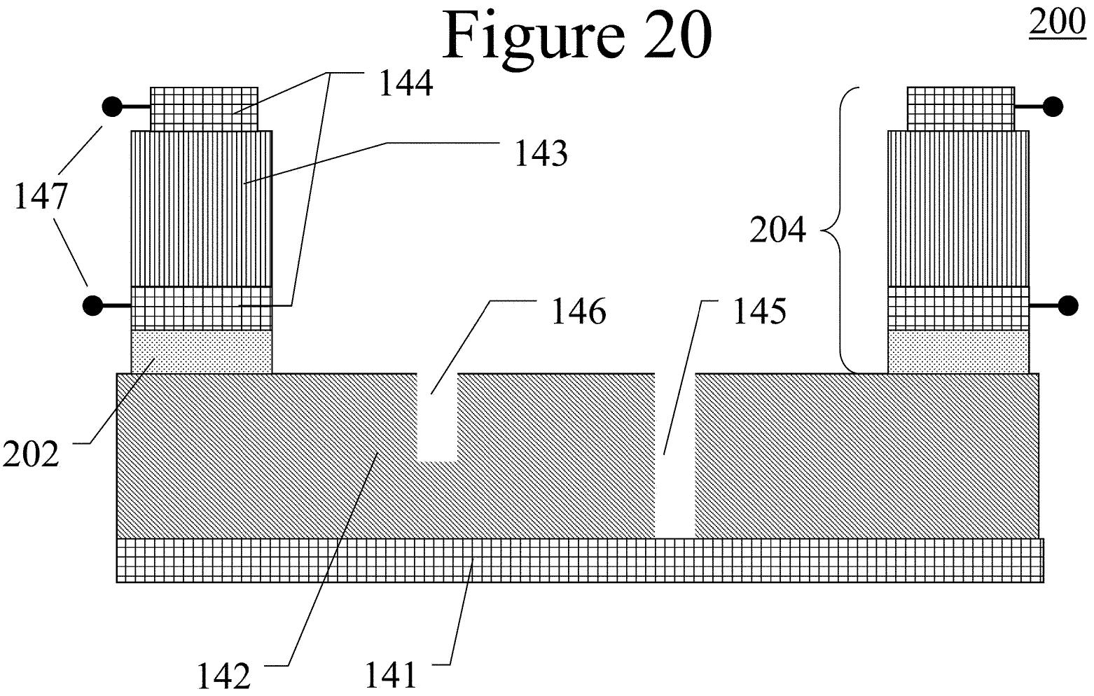

FIG. 20 is a diagram that depicts a cross-section 200 of embodiment 190 presented on FIG. 19. The lower conductive electrode is the layer 141. The cavity material is the layer 142. Layer 142 can be a linear, non-linear, piezoelectric, electrostrictive or photoelastic material or stack of materials. This layer contains patterned holes or inclusions that may go through the entire thickness of the layer 145, or partial through the thickness of the layer 146. The TE-or LE-mode transducer 204 is placed on top of the cavity 142. It consists of conductive top and bottom electrode 144, a piezoelectric layer 143. The piezoelectric layer 143 can additionally have electrostrictive or photoelastic properties. The conductive electrode layers 144 are on top and bottom of the piezoelectric layer 143. They form the electrical ports 147 to which the AWRC device is connected to other circuits. Acoustic coupler 202 can optionally be used to decouple the electrical response of the transducer 204 from its mechanical influence on the cavity. . The acoustic coupler 202 can consist of one or more material layers. The suspension structure layers are not shown. Optional passive temperature compensation layers are not shown.

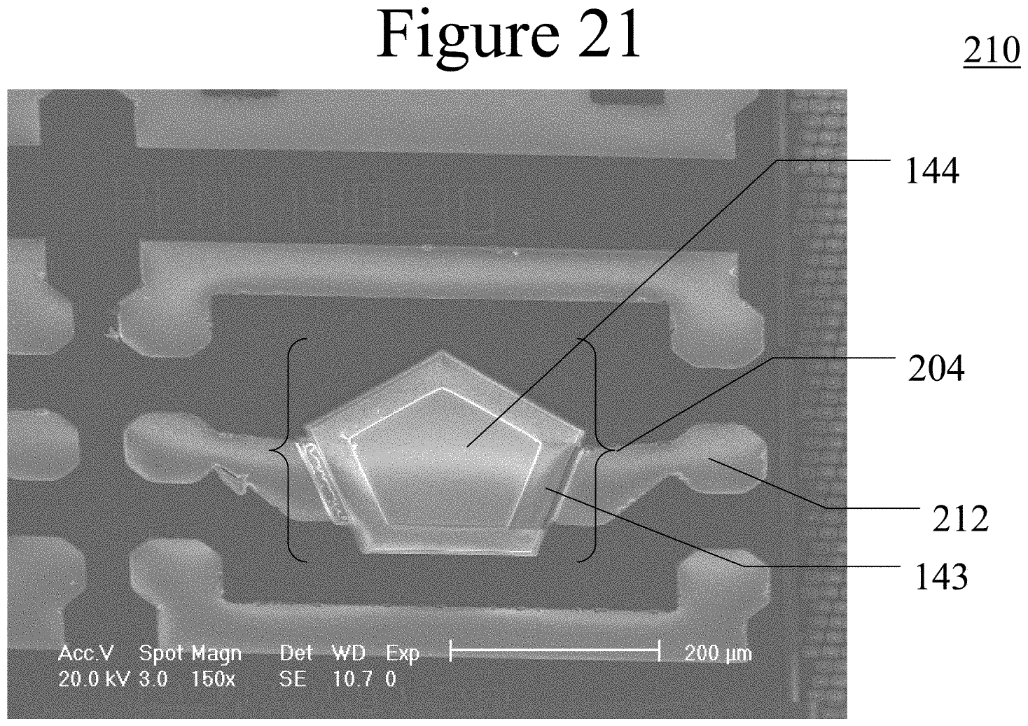

FIG. 21 is a Scanning-Electron Microscope (SEM) image 210 of a test structure for a TE-mode transducer 204, from embodiment 190 presented on FIG. 19. In the image, piezoelectric material 143, and top electrode 144 are visible. The device is connected to two interconnection pads 212.

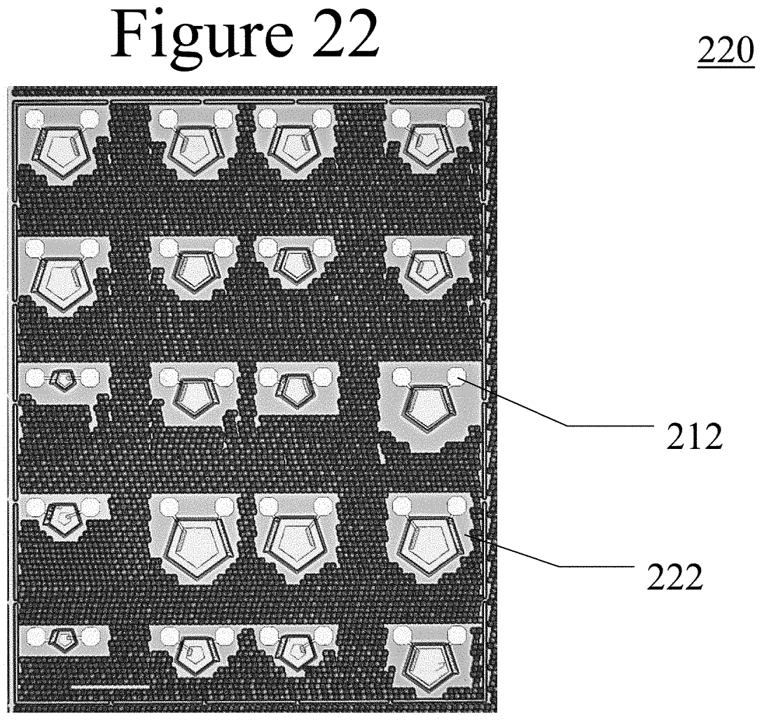

FIG. 22 is a SEM image 220 of a group of TE-mode transducers 222 that can be used with an acoustic wave reservoir. The cavity is not present in this test structure. Each transducer 222 has two electrical pads 212 for interconnection with other circuits. Transducers 222 can be used for input or output or may optionally be used for feedback, tuning, self-test or remain unused.

FIG. 23 is a diagram 230 that depicts a group of reservoirs 95A-95D that are composed to form a compound reservoir. The input signals 91A and 91B to the compound reservoir are applied at input transducers 92A and 92B of reservoirs 95A and 95B. The output signals 94C and 94D of the compound reservoir are read off output transducers 93C and 93D of reservoirs 95C and 95D. The reservoirs that form the compound reservoir are coupled to one another by electrical connections between transducers that are operated as simultaneously bi-directional transducers (e.g. 231A and 231C) as defined above. Each reservoir can have one or more connections (or no connection) to the other reservoirs that form the compound reservoir. Since electrical interconnects have comparatively low loss, the location of the simultaneously bi-directional transducers in one reservoir is not limited by physical proximity to other transducers in other reservoirs. The connections between all the reservoirs are denoted as coupling network 232. As described above, the coupling network 232 on diagram 230 is composed of passive electrical interconnects, but one skilled in the art will understand that active electrical interconnects (i.e. interconnects that provide gain, non-linearity, etc.) can be used, as well as mechanical interconnects, and other types of interconnects.

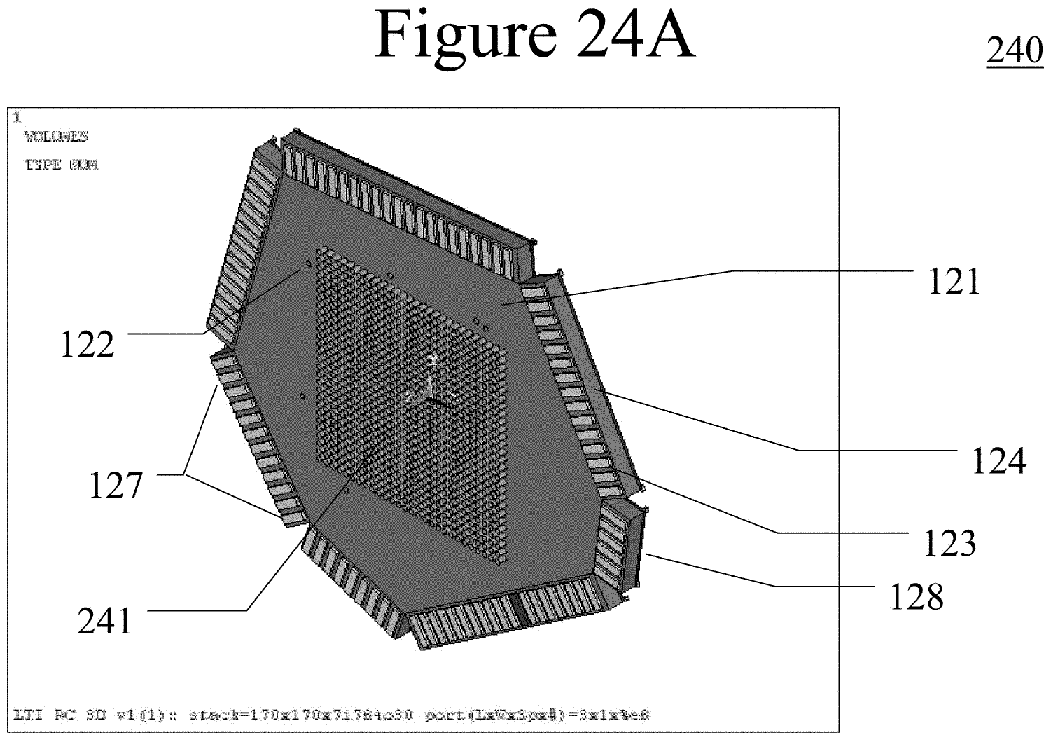

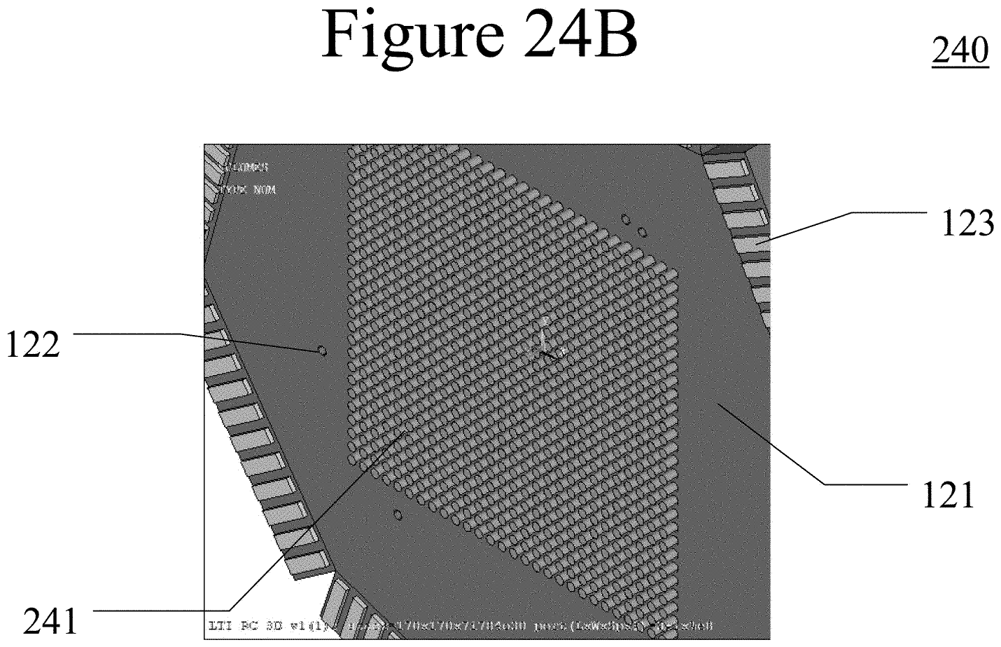

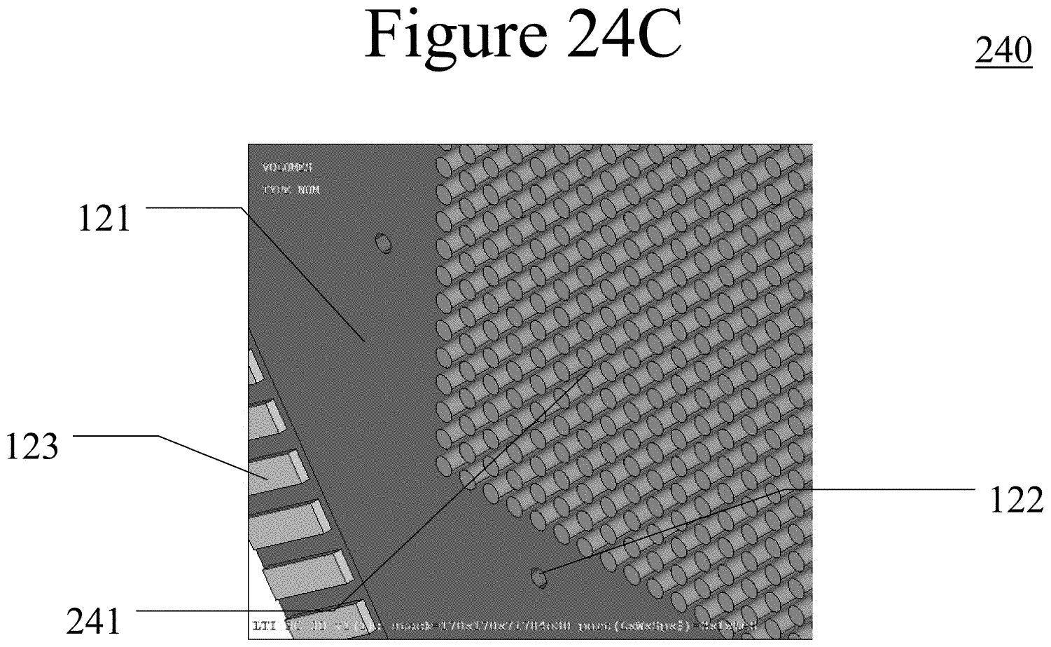

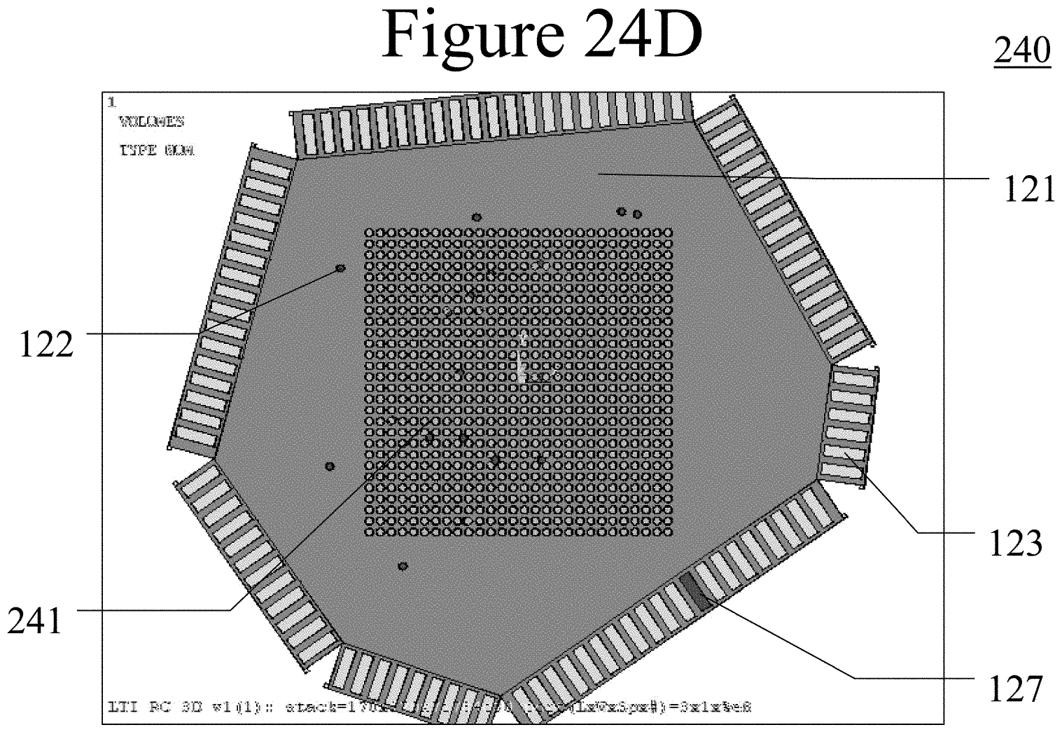

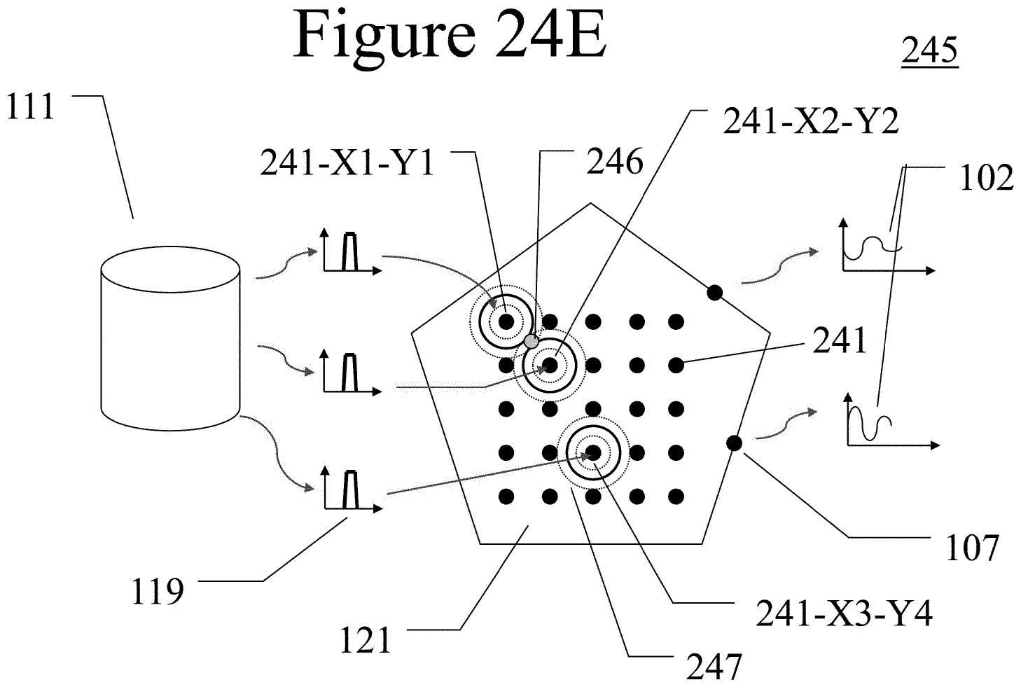

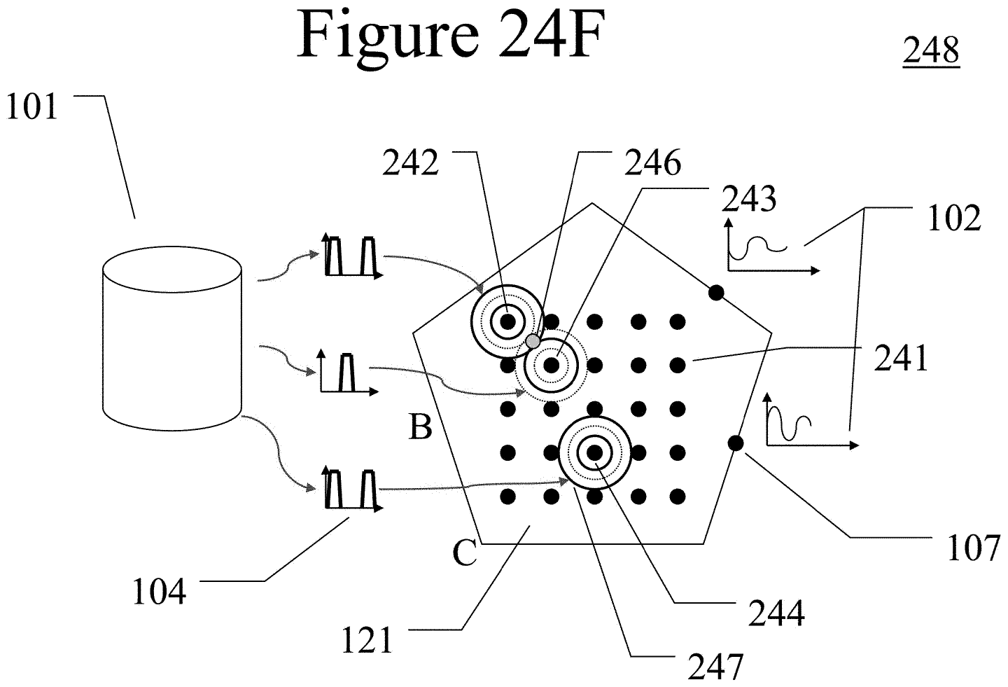

FIGS. 24A through 24D are diagrams that depict a finite-element solid model 240 of an alternate embodiment of a reservoir, where the input port transducers are located on top of the cavity and feed the input signals from the top. The model is drawn to scale in the plane, but layer thicknesses are exaggerated for clarity. FIGS. 24A through 24D show different views of the same structure. The cavity 121 has an asymmetric geometry as well as internal boundaries 122, in the form of through-holes. The cavity is surrounded by piezoelectric TE-mode transducer layer 124. Passive or active temperature compensation of the transducer response is optionally included. Each top conductive electrode 123 defines a transducer. A lower conductive electrode layer 128 is present under at least the transducer layer 124. Electrode layer 128 may also be present under the cavity 121. In this embodiment, all output ports 127 are located on the periphery of the reservoir. Some of the transducers defined by top conductive electrode 123 at the periphery of the reservoir may optionally be used for feedback, self-test or remain unused. In this embodiment, the input transducers 241 are placed on top of the cavity and feed the input signal from the top. The internal structure of transducers 241 is not shown. This particular embodiment is configured for the MNIST image recognition benchmark. As a consequence, the input transducers are configured in a 28×28 array, one for each pixel in the 28×28 images in the MNIST benchmark.

FIG. 24E is a simplified and idealized diagram 245 of the solid model 240 depicted on FIGS. 24A-24D, showing a possible operating mode of the embodiment for image analysis. Diagram 245 is simplified and has a 5×5 array of input transducers 241 located on the top surface of the cavity 121. FIG. 24E shows that input data (such as pixels from an image) is selected from input data source 111 (such as an image) and is input onto the cavity 121 via transducers 241 arrayed on the cavity. Each input data is converted to an input signal 119, via a suitable encoding scheme. The input signals are then applied onto the cavity 121 simultaneously via transducers 241. The transducers 241 convert the applied voltage to differential strains, which then propagate into the cavity as waves 247. As shown in FIG. 24E, at the instant of operation depicted on the Figure, the waves produced by transducers 241-X1-Y1 and 241-X2-Y2 have undergone superposition (i.e. the wave generated by input transducer 241-X1-Y1 has reached the wave generated by input transducer 241-X2-Y2) at point 246 in the cavity, but the waves produced by input transducer 241-X3-Y4 have yet to undergo superposition with the waves generated by either input transducer 241-X1-Y1 or 241-X2-Y2.

More generally, waves generated by two input transducers that are adjacent will interact with each other before they interact with waves generated by input transducers that are separated by a longer distance.

When the input data (e.g. pixels from an image) has a geometrical structure (e.g. the data source is an image, which is formed by a 2D array of pixels), and the input transducers located on the cavity 121 has an identical geometrical structure (e.g. a 2D array structure), and the input data is applied to the input transducers with a mapping that preserves the geometrical structure of the input data (e.g. pixels located at opposite corners of the source image are applied to the cavity at opposite corners of the array of input transducers), then as a consequence the physics of elastic wave propagation in the cavity, pixels close to each other interact with each other before pixels that are further apart. This behavior is repeated at all scales, viz. 2×2, 3×3, 4×4, etc. This may be interpreted as the reservoir applying a convolutional kernel to the image. After a period of time, the transducers at output ports 107 sense the arriving waves 247, and convert it to output voltage time series 102.

FIG. 24F is a simplified and idealized diagram of the solid model depicted on FIGS. 24A through 24D, showing a possible operating mode of the embodiment for the analysis of video frames. The significant change from FIG. 24fF is in the time series 104. In FIG. 24e, each pixel was encoded into the time series 104; here in FIG. 24F, the pixel and its change over video time is encoded into the time series 104.

FIG. 25A through 25C are diagrams that depict a finite-element solid model 250 of an alternate embodiment of a reservoir, where one or more LE-mode transducer pairs are configured to generate rotational waves. The model is drawn to scale in the plane, but layer thicknesses are exaggerated for clarity. Successive sub-figures ‘a’ through ‘c’ show different view of the same structure. The cavity 121 has an asymmetric geometry as well as internal boundaries 122, in the form of through-holes. The cavity is surrounded by piezoelectric LE-mode transducers 124. Passive or active temperature compensation of the transducer response is optionally included. A pair of top conductive electrodes 123 defines a port. The ports are used for input and output and may optionally be used for feedback, self-test or remain unused. The suspension structure is not shown.

FIG. 25D is a diagram of two transducers combined to form a single rotational transducer of four electrodes 252 through 255. Each pair of electrodes is stimulated in a selected order, to generate a rotational strain. Other electrode arrangements are possible, but not discussed here.

FIG. 25E is a diagram that depicts an example of a particular order of electrode stimulation of the rotational transducer of FIG. 25D, in order to launch a torsional wave into the cavity. At time t₁, the electrode pair 253 and 255 is stimulated. This launches a strain wave 256. At time t₂, the stimulated pair is switched to electrode pair 253 and 252. This launches strain wave 257. At time t3, the stimulated pair is switched to electrodes 252 and 254, resulting in the strain wave 258. Then at time t4, the stimulated pair is switched to electrodes 254 and 253, resulting in the strain wave 259. Other methods of electrode stimulation are possible, but not discussed here.

FIG. 25F is a diagram that depicts the rotational strain wave 251 that results from the application of the stimulus shown on FIG. 25E. The wave propagates into the cavity 121.

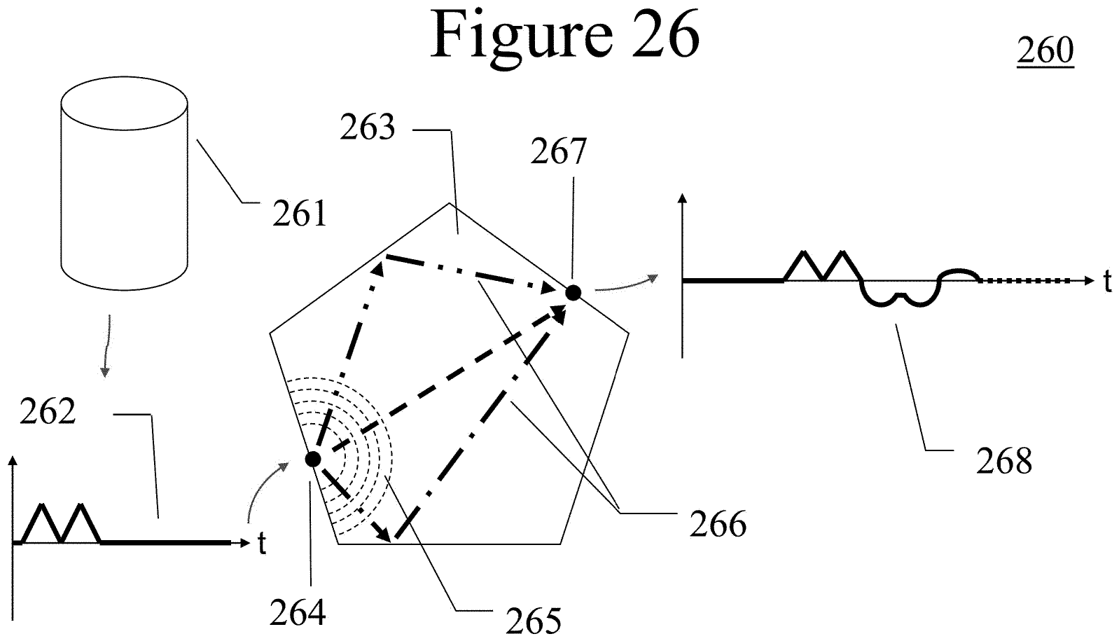

FIG. 26 is a diagram 260 that depicts a reservoir that is connected to one of more sensors 261, and how a sensor or group of sensors can provide time series output 262 of voltages, forces, displacements or other stimuli. Time series 262 is fed into the reservoir cavity 263. The cavity 263 is shown to be a pentagon, but other asymmetrical shapes are applicable. The transducers and suspension are not shown. Each time-series 262 is input into the reservoir cavity 263 at input port 264. The positions of the input and output ports are chosen randomly on the periphery, top or bottom of the reservoir. The wavefronts 265 propagate through the reservoir cavity. Reflections 266 at external and internal (not shown) boundaries cause mode conversion, and increase the richness of the dynamics. After a period of time that is greater than the time series input time, and not more than the dissipation time of the reservoir, the outputs are read at output ports 267 as time series output 268.

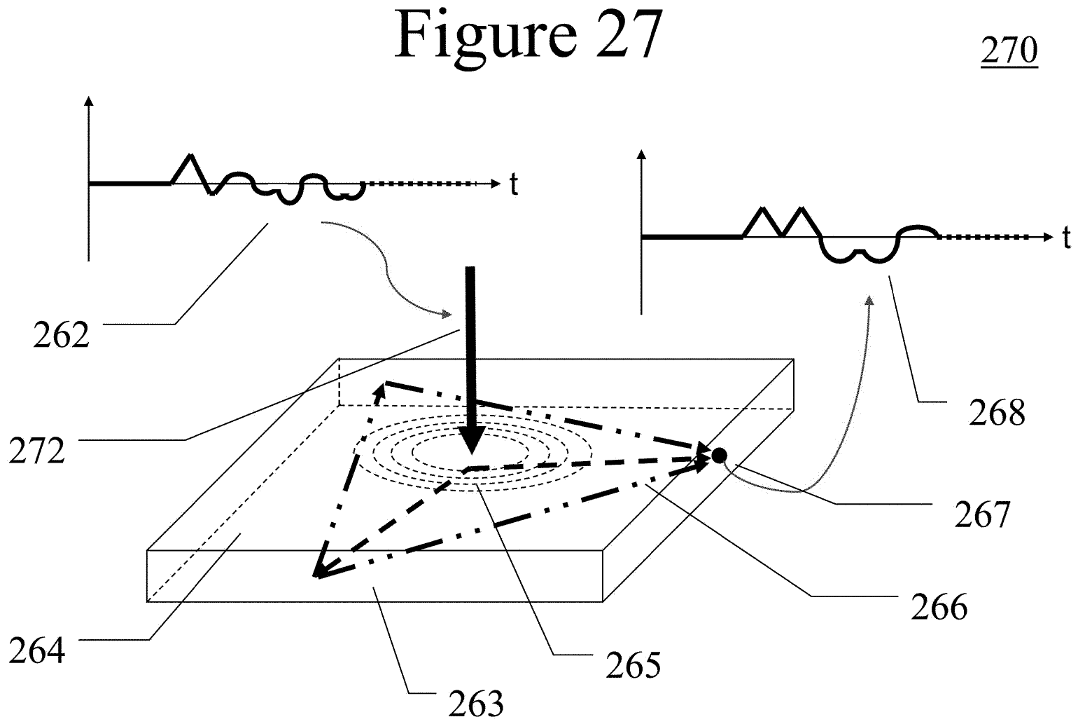

FIG. 27 is a diagram 270 that depicts a reservoir 263, whereon the reservoir cavity 263 can also perform sensing functions. Such functions include, without limitation, pressure sensing, microphony, etc. In diagram 270, the cavity is shown to react to an applied pressure 272. The transducers and suspension are not shown. In this embodiment, the input port 264 is the entire upper surface of the cavity. The positions of the output ports are chosen randomly on the periphery or bottom of the reservoir. Upon application of a time series pressure input 262, the cavity 263 displaces over time. The wavefronts 265 propagate through the reservoir cavity. Reflections 266 at external and internal (not shown) boundaries cause mode conversion, and increase the richness of the dynamics. After a period of time that is greater than the time series input time, and not more than the dissipation time of the reservoir, the outputs are read at output ports 267 as time series output 268.

From the foregoing and with reference to the various figure drawings, those skilled in the art will appreciate that certain modifications can also be made to the present disclosure without departing from the scope of the same. While several embodiments of the disclosure have been shown in the drawings, it is not intended that the disclosure be limited thereto, as it is intended that the disclosure be as broad in scope as the art will allow and that the specification be read likewise. Therefore, the above description should not be construed as limiting, but merely as exemplifications of particular embodiments. Those skilled in the art will envision other modifications within the scope and spirit of the claims appended hereto.

1. A wave propagation computing (WPC) device for computing random projections, the WPC device comprising:
a medium wherein the medium is an analog random projection medium; and
a plurality of boundaries that demarcate at least one active region in the medium as one or more cavities; and
a plurality of transducers connected to the medium, the plurality of transducers including at least one transducer to convert an electrical input signal into signal waves that propagate in the medium, and
the plurality of transducers including at least one transducer to convert the signal waves that propagate in the medium into an electrical output signal.

2. The WPC device of claim 1, wherein the medium comprises asymmetric geometric boundaries.

3. The WPC device of claim 1, wherein the medium provides non-linear propagation of the signal waves.

4. The WPC device of claim 1, wherein a transducer of the plurality of transducers provides a non-linear electrical output signal.

5. The WPC device of claim 1, wherein a transducer of the plurality of transducers is a microelectromechanical systems (MEMS) device.

6. The WPC device of claim 1, wherein the medium comprises a thin-film piezoelectric material.

7. The WPC device of claim 1, wherein the signal waves are selected from the group consisting of acoustic waves, elasto-acoustic waves, and electromagnetic waves.

8-9. (canceled)

10. The WPC device of claim 1 wherein the medium is demarcated by a plurality of surfaces to reflect the signal waves, the plurality of surfaces forming a three-dimensional structure.

11. The WPC device of claim 1, wherein the medium provides a multi-resonant frequency response over at least one decade in frequency.

12. The WPC device of claim 1, wherein the medium has internal impedance discontinuities wherein the internal impedance discontinuities are one or more of structure and material discontinuities.

13. (canceled)

14. The WPC device of claim 12, wherein the medium comprises one or more of a through hole, a partial hole, a local thickness increase, or a particulate/material inclusion.

15. (canceled)

16. The WPC device of claim 1, wherein the medium comprises two or more mediums.

17. The WPC device of claim 1, wherein at least two of the transducers are electrically connected via an optional external circuit to form one of a feedback path or a self-test path.

18. (canceled)

19. WPC device of claim 1, wherein the medium comprises a tunable propagation medium with one or more material properties that can be altered after manufacturing in a repeatable manner wherein the material properties comprise one or more of a coefficient of a stiffness matrix, a modulus of elasticity, a Poisson ratio, or a wave velocity.

20. (canceled)

21. The WPC device of claim 19, wherein the material properties can be altered by application of an electric field.

22. The WPC device of claim 1, wherein the plurality of transducers are positioned either along a lateral periphery of the medium, within an interior of the medium, or across a surface of the medium.

23-24. (canceled)

25. The WPC device of claim 1 further comprising:
a substrate; and
a suspension structure connecting the one or more cavities to the substrate, wherein the suspension structure isolates the one or more cavities from a cavity environment wherein the medium is formed by a Micro-Electro-Mechanical Systems (MEMS) thin-film structure.

26. (canceled)

27. A compound WPC device comprising:
two or more of the WPC devices of claim 1; and
an interconnect architecture connecting the two or more of the WPC devices.

28. The compound WPC device of claim 27, wherein the interconnect architecture is selected from the group consisting of a MEMS structure and an electrical circuit.

29. (canceled)

30. A method for performing computations with an analog random projection device, the method comprising:
sending a plurality of electrical input signals to a plurality of input transducers connected to an analog random projection device, wherein the input transducers convert the electrical input signals into signal waves to propagate in a medium of the analog random projection device;
physically propagating the signal waves within the medium; and
receiving a plurality of electrical output signals from a plurality of output transducers connected to the medium, wherein the output transducers generate the electrical output signals from the signal waves that propagate in the medium.

31. The method of claim 30 further comprising processing the electrical input signals or the electrical output signals, or both, to perform one or more of signal processing and machine learning operations.

32. (canceled)

33. The method of claim 30, wherein the medium comprises at least one of an asymmetric geometry or impedance discontinuities.

34. (canceled)

35. The method of claim 30, wherein at least two of the plurality of transducers are electrically connected to form a feedback path.
